(19) United States
(12) Patent Application Publication
(10) Pub. No.: US 2025/0162860 A1
(43) Pub. Date: May 22, 2025

(54) METHODS OF FABRICATING MICRO ELECTRO-MECHANICAL SYSTEMS STRUCTURES

(71) Applicant: The University of British Columbia, Vancouver (CA)

(72) Inventors: Chang GE, Vancouver (CA); Edmond CRETU, Vancouver (CA)

(73) Assignee: The University of British Columbia, Vancouver, BC (CA)

(21) Appl. No.: 18/839,351

(22) PCT Filed: Feb. 18, 2022
(86) PCT No.: PCT/CA2022/050245

§ 371 Date: Aug. 16, 2024

(51) Int. Cl. B81C 1/00; B81B 3/00

(52) U.S. Cl. CPC B81C 1/00158; B81B 3/0021; B81B 2203/0127; B81B 2203/04; B81B 2207/012; B81B 2207/07; B81C 2201/0181; B81C 2201/019; B81C 2203/036; B81C 2203/054; B81C 2203/0792

(57) ABSTRACT

According to at least one embodiment, methods of fabricating micro electro-mechanical systems (MEMS) structures involving lamination of an electromechanical layer to a micromechanical structure are disclosed.

### FIELD

This disclosure relates generally to methods of fabricating micro electro-mechanical systems structures.

### RELATED ART

Known methods of fabricating micro electro-mechanical systems (MEMS) structures may be overly complex, time-consuming, and costly.

### SUMMARY

According to at least one embodiment, there is disclosed a method of fabricating a micro electro-mechanical systems (MEMS) structure, the method comprising: aligning a first layer of the MEMS structure with a second layer of the MEMS structure by positioning alignment posts through corresponding alignment openings in each of the first layer and the second layer; and when the alignment posts are positioned through the corresponding alignment openings, laminating the first layer to the second layer.

In some embodiments, positioning the alignment posts through the alignment openings comprises positioning at least one of the alignment posts through a corresponding one of the alignment openings in the first layer and through a corresponding one of the alignment openings in the second layer.

According to at least one embodiment, there is disclosed a method of fabricating a micro electro-mechanical systems (MEMS) structure, the method comprising laminating an intermediate conductive layer of an electromechanical layer of the MEMS structure to a structural layer of a micromechanical structure of the MEMS structure, the electromechanical layer further comprising an outer conductive layer and a piezoelectric layer between the intermediate conductive layer and the outer conductive layer, the micromechanical structure further comprising a spacing layer defining a space open to the structural layer, wherein laminating the intermediate conductive layer to the structural layer comprises positioning an actuatable portion of the electromechanical layer across the structural layer from the space, the actuatable portion of the electromechanical layer comprising at least a portion of the intermediate conductive layer, at least a portion of the piezoelectric layer, and at least a portion of the outer conductive layer.

In some embodiments, positioning the actuatable portion of the electromechanical layer across the structural layer from the space comprises positioning alignment posts through corresponding alignment openings in each of the electromechanical layer and the micromechanical structure.

In some embodiments, positioning the alignment posts through the alignment openings comprises positioning at least one of the alignment posts through a corresponding one of the alignment openings in the electromechanical layer and through a corresponding one of the alignment openings in the micromechanical structure.

In some embodiments: the first layer comprises an electromechanical layer comprising an intermediate conductive layer, an outer conductive layer, and a piezoelectric layer between the intermediate conductive layer and the outer conductive layer; the second layer comprises a micromechanical structure comprising a structural layer and a spacing layer defining a space open to the structural layer; aligning the first layer with the second layer comprises positioning an actuatable portion of the electromechanical layer across the structural layer from the space, the actuatable portion of the electromechanical layer comprising at least a portion of the intermediate conductive layer, at least a portion of the piezoelectric layer, and at least a portion of the outer conductive layer; and laminating the first layer to the second layer comprises laminating the intermediate conductive layer to the structural layer.

In some embodiments, laminating the intermediate conductive layer to the structural layer comprises laminating the piezoelectric layer to the structural layer.

In some embodiments, positioning the alignment posts through the alignment openings comprises positioning at least some of the alignment posts through corresponding alignment openings in the piezoelectric layer.

In some embodiments, the method further comprises removing alignment portions of the piezoelectric layer to create the alignment openings in the piezoelectric layer.

In some embodiments, removing the alignment portions of the piezoelectric layer comprises causing a laser to remove the alignment portions of the piezoelectric layer.

In some embodiments, positioning the alignment posts through the alignment openings comprises positioning at least some of the alignment posts through corresponding alignment openings in the structural layer.

In some embodiments, the method further comprises removing alignment portions of the structural layer to create the alignment openings in the structural layer.

In some embodiments, removing the alignment portions of the structural layer comprises causing a laser to remove the alignment portions of the structural layer.

In some embodiments, positioning the alignment posts through the alignment openings comprises positioning at least some of the alignment posts through corresponding alignment openings in the spacing layer.

In some embodiments, the method further comprises removing alignment portions of the spacing layer to create the alignment openings in the spacing layer.

In some embodiments, removing the alignment portions of the spacing layer comprises causing a laser to remove the alignment portions of the spacing layer.

In some embodiments, positioning the alignment posts through the alignment openings comprises positioning at least three alignment posts through the alignment openings.

In some embodiments, positioning the alignment posts through the alignment openings comprises positioning the electromechanical layer and the micromechanical structure onto an alignment reference board comprising the alignment posts.

In some embodiments, the method further comprises manufacturing the alignment reference board.

In some embodiments, manufacturing the alignment reference board comprises 3D printing.

In some embodiments, manufacturing the alignment reference board comprises computer numerical controlled (CNC) machining.

In some embodiments, the method further comprises laminating the spacing layer to a support frame.

In some embodiments, laminating the spacing layer to the support frame comprises: depositing a support-frame adhesive layer onto the support frame; and overlaying the spacing layer with the support-frame adhesive layer.

In some embodiments, the support-frame adhesive layer comprises double-sided transfer tape.

In some embodiments, the method further comprises removing alignment portions of the support-frame adhesive layer to create alignment openings in the support-frame adhesive layer before depositing the support-frame adhesive layer onto the support frame, the alignment openings in the support-frame adhesive layer corresponding to at least some of the alignment openings in the electromechanical layer and the micromechanical structure.

In some embodiments, removing the alignment portions of the support-frame adhesive layer comprises causing a laser to remove the alignment portions of the support-frame adhesive layer.

In some embodiments, depositing the support-frame adhesive layer onto the support frame comprises spin-coating.

In some embodiments, the support-frame adhesive layer comprises polypropylene carbonate.

In some embodiments, laminating the spacing layer to the support frame comprises positioning support posts of the support frame through the alignment openings.

In some embodiments, the method further comprises manufacturing the support frame. In some embodiments, manufacturing the support frame comprises 3D printing.

In some embodiments, manufacturing the support frame comprises computer numerical controlled (CNC) machining.

In some embodiments, the method further comprises depositing the intermediate conductive layer onto the piezoelectric layer before laminating the intermediate conductive layer to the structural layer.

In some embodiments, the method further comprises: overlaying the piezoelectric layer with an intermediate shadow mask before depositing the intermediate conductive layer onto the piezoelectric layer; and removing the intermediate shadow mask after depositing the intermediate conductive layer onto the piezoelectric layer and before laminating the intermediate conductive layer to the structural layer, wherein the intermediate shadow mask is configured to mask an intermediate masked portion of the piezoelectric layer from deposition of the intermediate conductive layer when the intermediate shadow mask is overlayed with the piezoelectric layer.

In some embodiments, the intermediate shadow mask defines an intermediate shadow mask opening configured to expose an intermediate exposed portion of the piezoelectric layer to deposition of the intermediate conductive layer when the intermediate shadow mask is overlayed with the piezoelectric layer.

In some embodiments, the method further comprises removing a portion of the intermediate shadow mask to create the intermediate shadow mask opening.

In some embodiments, removing the portion of the intermediate shadow mask comprises causing a laser to remove the portion of the intermediate shadow mask.

In some embodiments, overlaying the piezoelectric layer with the intermediate shadow mask comprises positioning at least some of the alignment posts through corresponding alignment openings in the intermediate shadow mask.

In some embodiments, the method further comprises removing alignment portions of the intermediate shadow mask to create the alignment openings in the intermediate shadow mask.

In some embodiments, removing the alignment portions of the intermediate shadow mask comprises causing a laser to remove the alignment portions of the intermediate shadow mask.

In some embodiments, the intermediate shadow mask comprises a polymer.

In some embodiments, the intermediate shadow mask comprises polyimide.

In some embodiments, the intermediate shadow mask comprises glass.

In some embodiments, the intermediate shadow mask comprises silicon.

In some embodiments, the intermediate shadow mask comprises a metal.

In some embodiments, depositing the intermediate conductive layer onto the piezoelectric layer comprises physical vapor deposition

In some embodiments, depositing the intermediate conductive layer onto the piezoelectric layer comprises electron-beam evaporation.

In some embodiments, the method further comprises depositing the outer conductive layer onto the piezoelectric layer.

In some embodiments, the method further comprises: overlaying the piezoelectric layer with an outer shadow mask before depositing the outer conductive layer onto the piezoelectric layer; and removing the outer shadow mask after depositing the outer conductive layer onto the piezoelectric layer, wherein the outer shadow mask is configured to mask an outer masked portion of the piezoelectric layer from deposition of the outer conductive layer when the outer shadow mask is overlayed with the piezoelectric layer.

In some embodiments, the outer shadow mask defines an outer shadow mask opening configured to expose an outer exposed portion of the piezoelectric layer to deposition of the outer conductive layer when the outer shadow mask is overlayed with the piezoelectric layer.

In some embodiments, the method further comprises removing a portion of the outer shadow mask to create the outer shadow mask opening.

In some embodiments, removing the portion of the outer shadow mask comprises causing a laser to remove the portion of the outer shadow mask.

In some embodiments, overlaying the piezoelectric layer with the outer shadow mask comprises positioning at least some of the alignment posts through corresponding alignment openings in the outer shadow mask.

In some embodiments, the method further comprises removing alignment portions of the outer shadow mask to create the alignment openings in the outer shadow mask.

In some embodiments, removing the alignment portions of the outer shadow mask comprises causing a laser to remove the alignment portions of the outer shadow mask.

In some embodiments, the outer shadow mask comprises a polymer.

In some embodiments, the outer shadow mask comprises polyimide.

In some embodiments, the outer shadow mask comprises glass.

In some embodiments, the outer shadow mask comprises silicon.

In some embodiments, the outer shadow mask comprises a metal.

In some embodiments, depositing the outer conductive layer onto the piezoelectric layer comprises physical vapor deposition.

In some embodiments, depositing the outer conductive layer onto the piezoelectric layer comprises electron-beam evaporation.

In some embodiments, the space has a generally circular opening to the structural layer.

In some embodiments, the method further comprises removing a circular portion of the piezoelectric layer to create a circular opening in the piezoelectric layer before laminating the intermediate conductive layer to the structural layer, the circular opening in the piezoelectric layer having a radius that is less than a radius of the opening of the space to the structural layer, wherein positioning the actuatable portion of the electromechanical layer across the structural layer from the space comprises positioning the circular opening in the piezoelectric layer coaxial with the opening of the space to the structural layer.

In some embodiments, removing the circular portion of the piezoelectric layer comprises causing a laser to remove the circular portion of the piezoelectric layer.

In some embodiments, the method further comprises removing a portion of the spacing layer to create the space.

In some embodiments, removing the portion of the spacing layer comprises causing a laser to remove the portion of the spacing layer.

In some embodiments, laminating the intermediate conductive layer to the structural layer comprises: depositing a primary adhesive layer onto the structural layer; and overlaying the intermediate conductive layer with the primary adhesive layer.

In some embodiments, depositing the primary adhesive layer onto the structural layer comprises spin-coating.

In some embodiments, depositing the primary adhesive layer onto the structural layer comprises ultrasonic coating.

In some embodiments, the primary adhesive layer comprises an adhesive epoxy.

In some embodiments, the adhesive epoxy is SU-8 photoresist.

In some embodiments, the method further comprises laminating the structural layer to the spacing layer before laminating the intermediate conductive layer to the structural layer.

In some embodiments, laminating the structural layer to the spacing layer comprises: depositing an internal adhesive layer onto the spacing layer; and overlaying the structural layer with the internal adhesive layer.

In some embodiments, depositing the internal adhesive layer onto the spacing layer comprises spin-coating.

In some embodiments, depositing the internal adhesive layer onto the spacing layer comprises ultrasonic coating.

In some embodiments, the internal adhesive layer comprises an adhesive epoxy.

In some embodiments, the adhesive epoxy is SU-8 photoresist.

In some embodiments, the method further comprises wire bonding the intermediate conductive layer to an external circuit through a conduit in the micromechanical structure after laminating the intermediate conductive layer to the structural layer, the conduit open to the intermediate conductive layer and to an environment external to the MEMS structure, the external environment comprising the external circuit.

In some embodiments, the structural layer defines a proximal portion of the conduit and the spacing layer defines a distal portion of the conduit.

In some embodiments, the method further comprises removing a portion of the structural layer to create the proximal portion of the conduit.

In some embodiments, removing the portion of the structural layer comprises causing a laser to remove the portion of the structural layer.

In some embodiments, the method further comprises removing a portion of the spacing layer to create the distal portion of the conduit.

In some embodiments, removing the portion of the spacing layer comprises causing a laser to remove the portion of the spacing layer.

In some embodiments, wire bonding the intermediate conductive layer to the external circuit comprises bonding a first wire to a contact region of the intermediate conductive layer, the contact region of the intermediate conductive layer separate from a moving region of the intermediate conductive layer across the structural layer from the space.

In some embodiments, the method further comprises wire bonding the outer conductive layer to the external circuit, wherein wire bonding the outer conductive layer to the external circuit comprises bonding a second wire to a contact region of the outer conductive layer, the contact region of the outer conductive layer non-overlapping the contact region of the intermediate conductive layer.

In some embodiments, the contact region of the outer conductive layer is separate from a moving region of the outer conductive layer across the piezoelectric layer, the intermediate conductive layer, and the structural layer from the space.

In some embodiments, the intermediate conductive layer comprises a first electrode of the electromechanical layer and the outer conductive layer comprises a second electrode of the electromechanical layer.

In some embodiments, the structural layer comprises a polymer.

In some embodiments, the structural layer comprises polyimide.

In some embodiments, the structural layer comprises a Kapton™ polyimide film.

In some embodiments, the spacing layer comprises a polymer.

In some embodiments, the spacing layer comprises polyimide.

In some embodiments, the spacing layer comprises a Kapton™ polyimide film.

In some embodiments, the piezoelectric layer comprises polyvinylidene difluoride (PVDF).

In some embodiments, the piezoelectric layer comprises polyvinylidene fluoride-trifluoroethylene (PVDF-TrFe).

In some embodiments, the intermediate conductive layer comprises a metal.

In some embodiments, the intermediate conductive layer comprises aluminum.

In some embodiments, the intermediate conductive layer comprises an aluminum nano film.

In some embodiments, the outer conductive layer comprises a metal.

In some embodiments, the outer conductive layer comprises aluminum.

In some embodiments, the outer conductive layer comprises an aluminum nano film.

In some embodiments, the piezoelectric layer has a thickness of less than 20 microns.

In some embodiments, the piezoelectric layer has a thickness of about 15 microns.

In some embodiments, the structural layer has a thickness of less than 30 microns.

In some embodiments, the structural layer has a thickness of about 25 microns.

In some embodiments, the structural layer has a thickness of about 12 microns.

In some embodiments, the spacing layer has a thickness of less than 200 microns.

In some embodiments, the spacing layer has a thickness of about 150 microns.

In some embodiments, the MEMS structure is a membrane-based piezoelectric device.

In some embodiments, the MEMS structure is a transducer.

In some embodiments, the MEMS structure is a mass sensor.

In some embodiments, the MEMS structure is a loudspeaker.

In some embodiments, the MEMS structure is a micropump.

According to at least one embodiment, there is disclosed a MEMS structure fabricated by the method.

Other aspects and features will become apparent to those ordinarily skilled in the art upon review of the following description of illustrative embodiments in conjunction with the accompanying figures.

### BRIEF DESCRIPTION OF THE DRAWINGS

It is intended that the embodiments and figures disclosed herein are to be considered illustrative rather than restrictive.

FIG. 1 is a flow chart of a method of fabricating micro electro-mechanical systems (MEMS) structures according to one embodiment.

FIG. 2 is a cross-sectional view of a MEMS structure fabricated according to the method of FIG. 1.

FIG. 3 is a top view of a structural layer of the MEMS structure of FIG. 2.

FIG. 4 is a cross-sectional view of the structural layer of FIG. 3, taken along the section line marked FIG. 4 in FIG. 3.

FIG. 5 is a top view of a spacing layer of the MEMS structure of FIG. 2.

FIG. 6 is a cross-sectional view of the spacing layer of FIG. 5, taken along the section line marked FIG. 6 in FIG. 5.

FIG. 7 is a top view of an alignment reference board used in the method of FIG. 1 to fabricate the MEMS structure of FIG. 2.

FIG. 8 is a cross-sectional view of the alignment reference board of FIG. 7, taken along the section line marked FIG. 8 in FIG. 7.

FIG. 9 is a cross-sectional view of the structural layer of FIGS. 3 and 4 overlayed with the alignment reference board of FIGS. 7 and 8 during fabrication of the MEMS structure of FIG. 2 according to the method of FIG. 1.

FIG. 10 is a cross-sectional view of the spacing layer of FIGS. 5 and 6 and an internal adhesive layer of the MEMS structure of FIG. 2.

FIG. 11 is a cross-sectional view of the spacing layer and internal adhesive layer of FIG. 10 overlayed with the structural layer and alignment reference board of FIG. 9 during fabrication of the MEMS structure of FIG. 2 according to the method of FIG. 1.

FIG. 12 is a cross-sectional view of a micromechanical structure of the MEMS structure of FIG. 2.

FIG. 13 is a top view of a piezoelectric layer of the MEMS structure of FIG. 2.

FIG. 14 is a cross-sectional view of the piezoelectric layer of FIG. 13, taken along a section line marked FIG. 14 in FIG. 13.

FIG. 15 is a top view of an intermediate shadow mask used in the method of FIG. 1 to fabricate the MEMS structure of FIG. 2.

FIG. 16 is a cross-sectional view of the intermediate shadow mask of FIG. 15, taken along a section line marked FIG. 16 in FIG. 15.

FIG. 17 is a cross-sectional view of the intermediate shadow mask of FIGS. 15 and 16 overlayed with the piezoelectric layer of FIGS. 13 and 14 and the alignment reference board of FIGS. 7 and 8 during fabrication of the MEMS structure of FIG. 2 according to the method of FIG. 1.

FIG. 18 is a cross-sectional view of the intermediate shadow mask, piezoelectric layer, and alignment reference board of FIG. 17 with an intermediate conductive layer of the MEMS structure of FIG. 2 deposited onto the piezoelectric layer.

FIG. 19 is a top view of an outer shadow mask used in the method of FIG. 1 to fabricate the MEMS structure of FIG. 2.

FIG. 20 is a cross-sectional view of the outer shadow mask of FIG. 19, taken along a section line marked FIG. 20 in FIG. 19.

FIG. 21 is a cross-sectional view of the outer shadow mask of FIGS. 19 and 20 overlayed with the piezoelectric layer and intermediate conductive layer of FIG. 18 and the alignment reference board of FIGS. 7 and 8 during fabrication of the MEMS structure of FIG. 2 according to the method of FIG. 1.

FIG. 22 is a cross-sectional view of the outer shadow mask, piezoelectric layer and intermediate conductive layer, and alignment reference board of FIG. 21 with an outer conductive layer of the MEMS structure of FIG. 2 deposited onto the piezoelectric layer.

FIG. 23 is a top view of an electromechanical layer of the MEMS structure of FIG. 2.

FIG. 24 is a cross-sectional view of the electromechanical layer of FIG. 23, taken along a section line marked FIG. 24 in FIG. 23.

FIG. 25 is a cross-sectional view of the electromechanical layer of FIGS. 23 and 24 overlayed with the alignment reference board of FIGS. 7 and 8 during fabrication of the MEMS structure of FIG. 2 according to the method of FIG. 1.

FIG. 26 is a cross-sectional view of the micromechanical structure of FIG. 12 and a primary adhesive layer of the MEMS structure of FIG. 2.

FIG. 27 is a cross-sectional view of the micromechanical structure and primary adhesive layer of FIG. 26 overlayed with the electromechanical layer and alignment reference board of FIG. 25 during fabrication of the MEMS structure of FIG. 2 according to the method of FIG. 1.

FIG. 28 is a cross-sectional view of an intermediate stage of the MEMS structure of FIG. 2 being fabricated according to the method of FIG. 1.

FIG. 29 is a top view of a support frame of the MEMS structure of FIG. 2.

FIG. 30 is a cross-sectional view of the support frame of FIG. 29, taken along a section line marked FIG. 30 in FIG. 29.

FIG. 31 is a top view of a support frame adhesive layer of the MEMS structure of FIG. 2.

FIG. 32 is a cross-sectional view of the support frame adhesive layer of FIG. 31, taken along a section line marked FIG. 32 in FIG. 31.

FIG. 33 is a cross-sectional view of the support frame adhesive layer of FIGS. 31 and 32 overlayed with the support frame FIGS. 29 and 30 during fabrication of the MEMS structure of FIG. 2 according to the method of FIG. 1.

FIG. 34 is a cross-sectional view of the MEMS structure of FIG. 2 wire bonded to an external circuit (not shown).

FIG. 35 is a top view of a piezoelectric layer of a MEMS structure fabricated according to another embodiment.

FIG. 36 is a cross-sectional view of the piezoelectric layer of FIG. 35, taken along a section line marked FIG. 36 in FIG. 35.

FIG. 37 is a top view of an electromechanical layer of the MEMS structure of the piezoelectric layer of FIGS. 35 and 36.

FIG. 38 is a cross-sectional view of the electromechanical layer of FIG. 37, taken along a section line marked FIG. 38 in FIG. 37.

FIG. 39 is a cross-sectional view of the MEMS structure of the piezoelectric layer of FIGS. 35 and 36 wire bonded to an external circuit (not shown).

FIG. 40 illustrates a mask design for laser micromachining of a spacing layer according to one embodiment.

FIG. 41 illustrates a mask design for laser micromachining of a structural layer according to one embodiment.

FIG. 42 illustrates a mask design for laser micromachining of a piezoelectric layer according to one embodiment.

FIG. 43 is a graph presenting finite element analysis results for a simulation of an electrical-to-mechanical coupling where a piezoelectric layer is overlayed with only an edge of a circular membrane.

FIG. 44 is a graph presenting finite element analysis results for a simulation of an electrical-to-mechanical coupling where a piezoelectric layer is fully overlayed with a circular membrane.

FIG. 45 is a graph presenting an average mechanical resonance frequency response spectrum for elements of a MEMS transducer array fabricated according to one embodiment.

FIG. 46 is a graph presenting a measured modal shape for a peak response on the mechanical resonance frequency response spectrum of FIG. 45.

FIG. 47 is a graph presenting electrical impedance measurement results for the MEMS transducer array characterized in FIG. 45.

FIG. 48 illustrates a mask design for laser micromachining of a structural layer according to one embodiment.

FIG. 49 illustrates an alignment marker cutout of the mask design of FIG. 48.

FIG. 50 illustrates a mask design for laser micromachining of a spacing layer according to one embodiment.

FIG. 51 illustrates a mask design for laser micromachining of a piezoelectric layer according to one embodiment.

FIG. 52 illustrates a mask design for SU-8 lithography of a micropillar array according to one embodiment.

FIG. 53 illustrates an alignment marker of the mask design of FIG. 52.

FIG. 54 is a graph presenting white-light interferometer measurement results for a representative SU-8 micropillar of a SU-8 micropillar array produced using the mask design of FIG. 52.

FIG. 55 is a graph presenting average mechanical resonance frequency response spectrums for elements of a loaded and an unloaded MEMS mass sensor array fabricated according to one embodiment

FIG. 56 is a graph presenting a measured modal shape for a fundamental resonant mode of the elements of the loaded array of FIG. 55.

FIG. 57 is a graph presenting a measured modal shape for a fundamental resonant mode of the elements of the unloaded array of FIG. 55.

### DETAILED DESCRIPTION

Micro electro-mechanical systems (MEMS) consist of sensors and actuators transferring information and energy between the electrical and mechanical domains. Methods of fabricating MEMS structures involving lamination of an electromechanical layer to a micromechanical structure are described herein. These methods are particularly suitable for producing membrane-based piezoelectric MEMS devices such as, for example, transducers, mass sensors, loudspeakers, and micropumps. Furthermore, the methods described herein may be used to fabricate such MEMS devices using primarily off-the-shelf polymeric sheets, reducing fabrication costs and time without sacrificing performance.

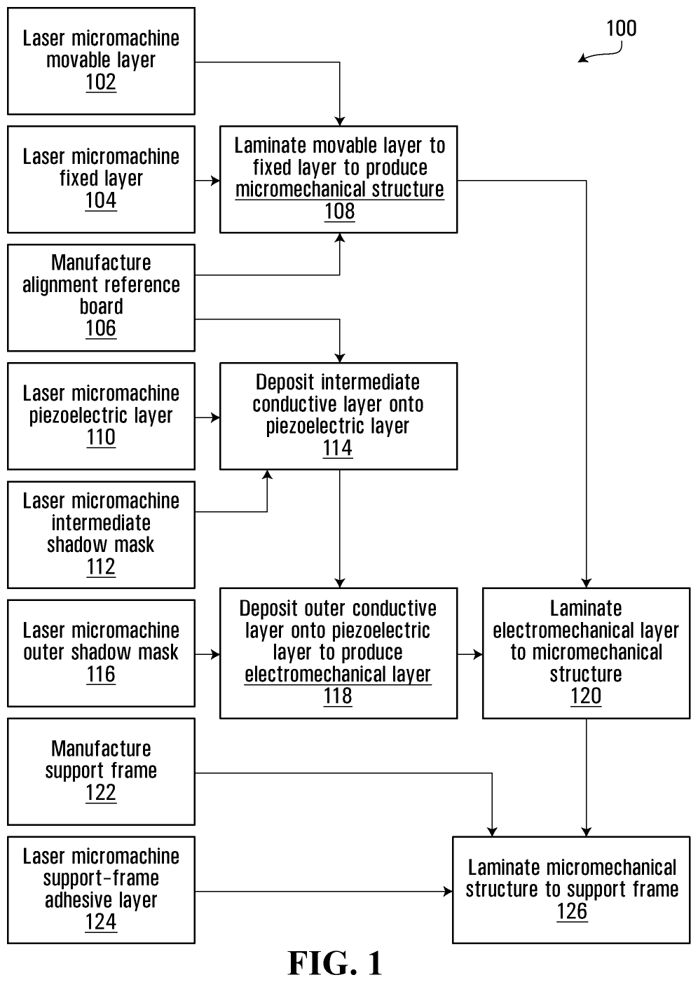

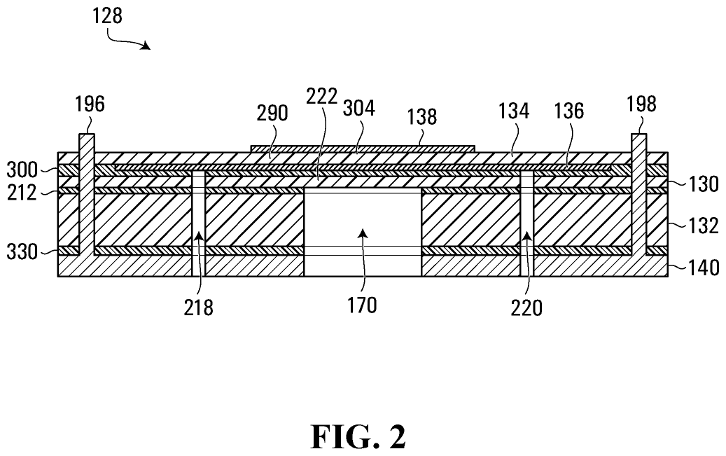

Referring to FIGS. 1 and 2, a method of fabricating a MEMS structure according to one embodiment is illustrated in a flowchart shown generally at 100, and a MEMS structure fabricated according to the method illustrated in the flowchart 100 is shown generally at 128, in a fully assembled state. In this fully assembled state, the MEMS structure 128 includes a structural layer 130 with movable regions, a spacing layer 132, a piezoelectric layer 134, an intermediate conductive layer 136, an outer conductive layer 138, and a support frame 140. Generally, the piezoelectric layer 134, the intermediate conductive layer 136, and the outer conductive layer 138 provide electromechanical coupling for the MEMS structure 128, while the structural layer 130, the spacing layer 132, and the support frame 140 provide structural support.

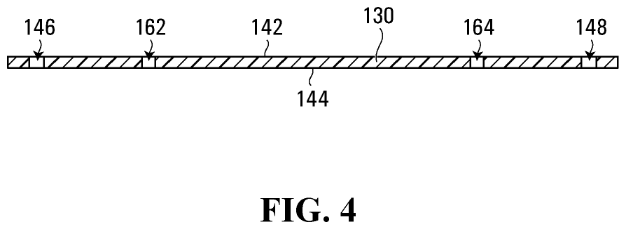

Referring to FIGS. 1, 3, and 4, in a first step of the method of this embodiment, at 102, the structural layer 130 is provided and includes a surface 142 and a surface 144 opposite the surface 142. The structural layer 130 is ablated using laser micromachining or equivalent techniques (e.g., mechanical micromachining) to remove portions of the structural layer 130 to produce alignment openings, shown generally at 146, 148, 150, 152, 154, 156, 158, and 160, and proximal conduit portions, shown generally at 162 and 164, in the structural layer 130.

In some embodiments, the structural layer 130 may include a polymer, such as, for example, polyimide. More specifically, the structural layer 130 may include a Kapton™ polyimide film. In some embodiments, the structural layer 130 may have a thickness of less than 30 microns. For example, the structural layer 130 may have a thickness of about 25 microns, or a thickness of about 12 microns. The structural layer 130 may also be referred to as a “movable layer”.

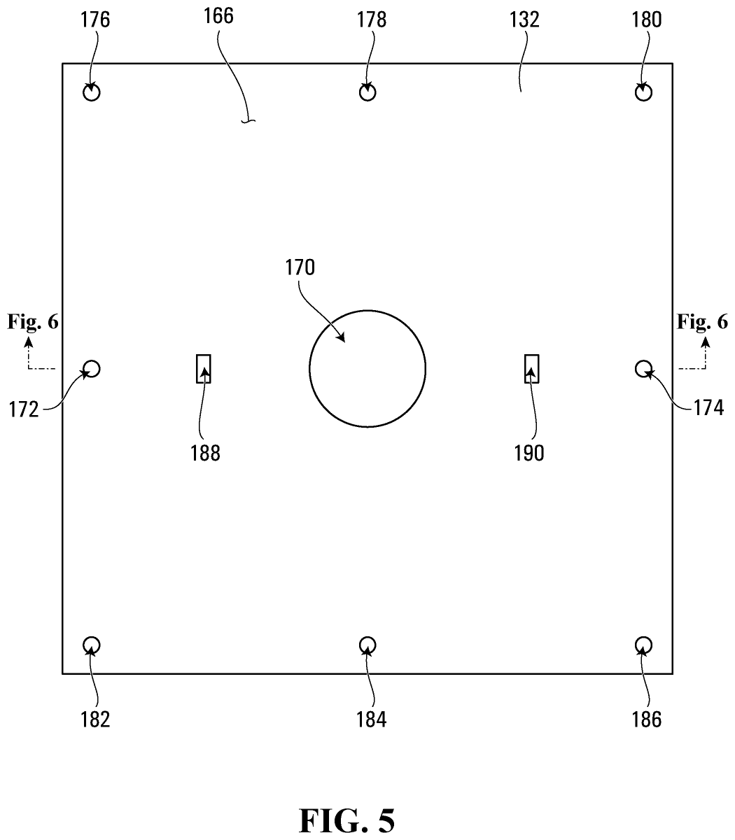

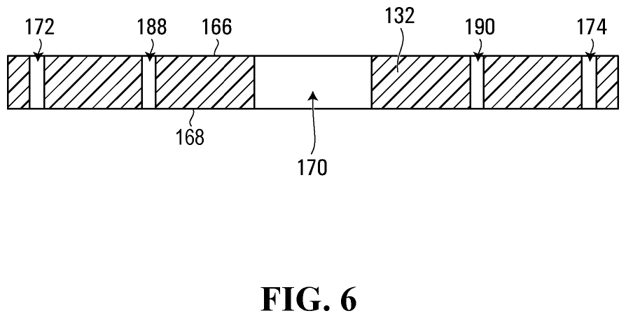

Referring to FIGS. 1, 5, and 6, in a second step of the method of this embodiment, at 104, the spacing layer 132 is provided and includes a surface 166 and a surface 168 opposite the surface 166. The spacing layer 132 is ablated using laser micromachining to remove portions of the spacing layer 132 to produce a space, shown generally at 170, alignment openings, shown generally at 172, 174, 176, 178, 180, 182, 184, and 186, and distal conduit portions, shown generally at 188 and 190, in the spacing layer 132. In the fully assembled

MEMS structure 128, the space 170 may allow regions of the structural layer 130 to move. In the method of this embodiment, the space 170 has a generally circular shape. However, in other embodiments, the space 170 may have a different shape, such as a rectangular shape or a hexagonal shape, depending on desired vibration modes and, for cell array patterns, on desired packing density of cell elements. Further, in some other embodiments, the spacing layer 132 may be ablated to produce a plurality of spaces in the spacing layer 132 rather than the single space 170.

In some embodiments, the spacing layer 132 may include a polymer, such as, for example, polyimide. More specifically, the spacing layer 132 may include a Kapton™ polyimide film. In some embodiments, the spacing layer 132 may have a thickness of less than 200 microns. For example, the spacing layer 132 may have a thickness of about 150 microns. The spacing layer 132 may also be referred to as a “spacer layer” or a “fixed layer”.

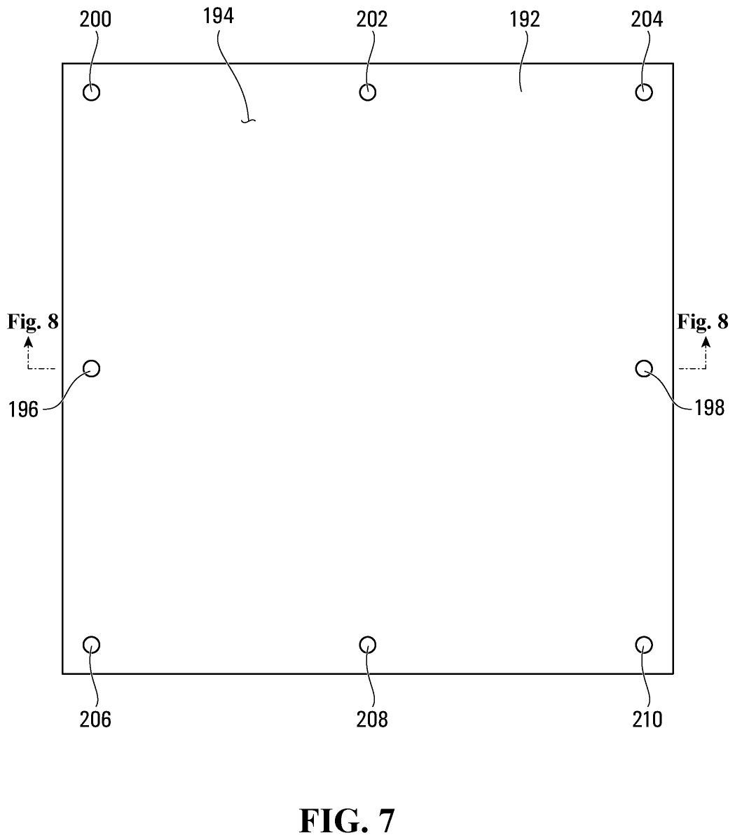

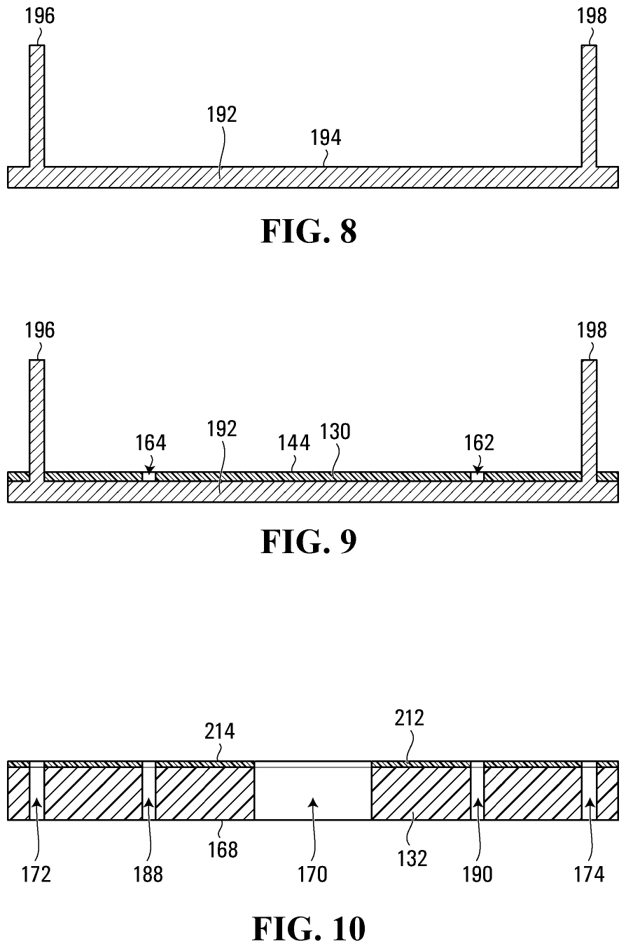

Referring now to FIGS. 1, 7, and 8, at 106, an alignment reference board 192 is manufactured using 3D printing. The alignment reference board 192 may comprise an ABS plastic or a metal. The alignment reference board 192 includes a surface 194 and alignment posts 196, 198, 200, 202, 204, 206, 208, and 210. Although in this embodiment 3D printing is used to manufacture the alignment reference board 192, in other embodiments, other methods may be used. For example, in some other embodiments, the alignment reference board 192 may be manufactured using computer numerical controlled (CNC) machining. As described below, the alignment posts 196, 198, 200, 202, 204, 206, 208, and 210 may serve as global (3D) alignment references to align patterns defined in the layers of the MEMS structure 128.

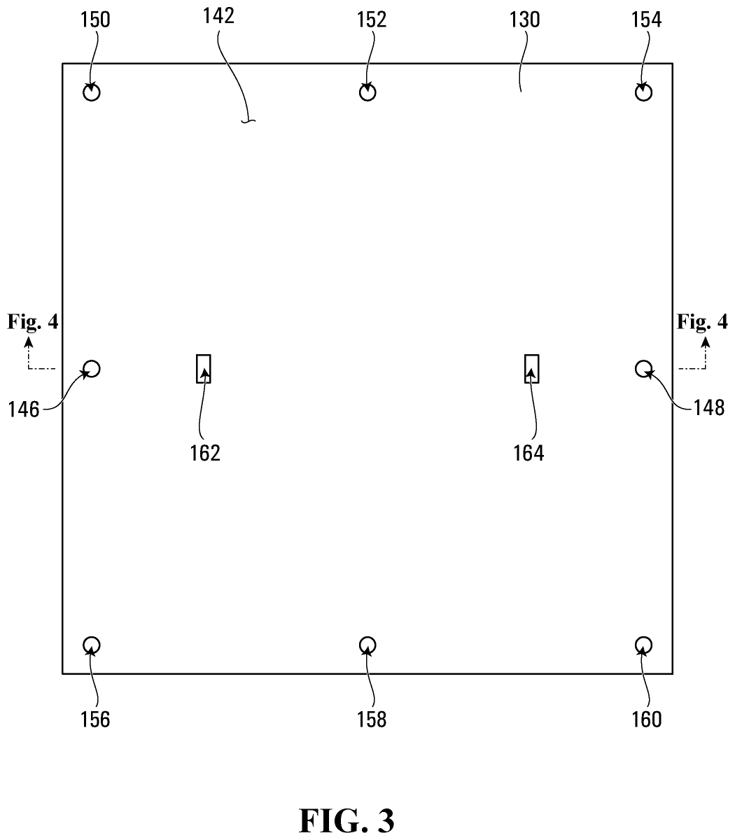

Referring now to FIGS. 3 to 8, the alignment openings 146, 148, 150, 152, 154, 156, 158, and 160 of the structural layer 130, the alignment openings 172, 174, 176, 178, 180, 182, 184, and 186 of the spacing layer 132, and the alignment posts 196, 198, 200, 202, 204, 206, 208, and 210 of the alignment reference board 192 are all located in corresponding positions on the structural layer 130, the spacing layer 132, and the alignment reference board 192, respectively. Therefore, the structural layer 130, the spacing layer 132, and the alignment reference board 192 can be overlayed with one another such that the alignment openings 146, 148, 150, 152, 154, 156, 158, and 160 of the structural layer 130 simultaneously line up with the alignment openings 172, 174, 176, 178, 180, 182, 184, and 186, respectively, of the spacing layer 132 and with the alignment posts 196, 198, 200, 202, 204, 206, 208, and 210, respectively, of the alignment reference board 192. When the structural layer 130, the spacing layer 132, and the alignment reference board 192 are overlayed in such a way, the alignment post 196 will be positioned to simultaneously pass through the alignment openings 172 and 146, the alignment post 198 will be positioned to simultaneously pass through the alignment openings 174 and 148, the alignment post 200 will be positioned to simultaneously pass through the alignment openings 176 and 150, the alignment post 202 will be positioned to simultaneously pass through the alignment openings 178 and 152, the alignment post 204 will be positioned to simultaneously pass through the alignment openings 180 and 154, the alignment post 206 will be positioned to simultaneously pass through the alignment openings 182 and 156, the alignment post 208 will be positioned to simultaneously pass through the alignment openings 184 and 158, and the alignment post 210 will be positioned to simultaneously pass through the alignment openings 186 and 160. This configuration of the alignment posts of the alignment reference board 192 with the alignment openings of the structural layer 130 and the spacing layer 132 may allow the alignment reference board 192 to be used to align the structural layer 130 with the spacing layer 132 during fabrication to ensure that features of the structural layer 130 overlay accurately with features of the spacing layer 132. For example, when the structural layer 130, the spacing layer 132, and the alignment reference board 192 are overlayed as described above, the proximal conduit portions 162 and 164 of the structural layer 130 will align with the distal conduit portions 188 and 190, respectively, of the spacing layer 132.

Referring to FIGS. 1 and 9 to 11, at 108, the structural layer 130 is laminated to the spacing layer 132. First, as shown in FIG. 9, the structural layer 130 is overlayed with the alignment reference board 192 such that the surface 142 of the structural layer 130 contacts the surface 194 of the alignment reference board 192, the surface 144 of the structural layer 130 remains exposed, the alignment post 196 is positioned through the alignment opening 148, the alignment post 198 is positioned through the alignment opening 146, the alignment post 200 is positioned through the alignment opening 154, the alignment post 202 is positioned through the alignment opening 152, the alignment post 204 is positioned through the alignment opening 150, the alignment post 206 is positioned through the alignment opening 160, the alignment post 208 is positioned through the alignment opening 158, and the alignment post 210 is positioned through the alignment opening 156.

Next, as shown in FIG. 10, an internal adhesive layer 212 is deposited onto the surface 166 of the spacing layer 132. The internal adhesive layer 212 includes a surface 214 which remains exposed when the internal adhesive layer 212 is deposited onto the spacing layer 132. In some embodiments, the internal adhesive layer 212 may be deposited onto the spacing layer 132 using spin-coating. In other embodiments, the internal adhesive layer 212 may be deposited onto the spacing layer 132 using ultrasonic coating. In some embodiments, the internal adhesive layer 212 may include an adhesive epoxy such as, for example, SU-8 photoresist.

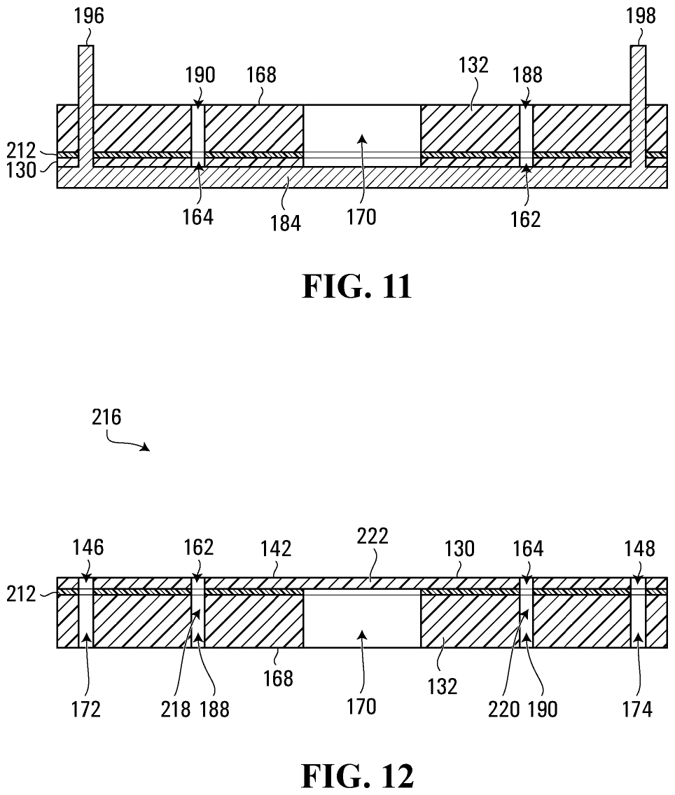

Finally, as shown in FIG. 11, the internal adhesive layer 212, with the spacing layer 132 attached, is overlayed with the structural layer 130 and the alignment reference board 192 such that the surface 214 of the internal adhesive layer 212 contacts the surface 144 of the structural layer 130, the alignment post 196 is positioned through the alignment opening 174, the alignment post 198 is positioned through the alignment opening 172, the alignment post 200 is positioned through the alignment opening 180, the alignment post 202 is positioned through the alignment opening 178, the alignment post 204 is positioned through the alignment opening 176, the alignment post 206 is positioned through the alignment opening 186, the alignment post 208 is positioned through the alignment opening 184, and the alignment post 210 is positioned through the alignment opening 182. Contact between the internal adhesive layer 212 and the structural layer 130 may cause the internal adhesive layer 212 to adhere to the structural layer 130, thus adhesively laminating the structural layer 130 to the spacing layer 132. The alignment reference board 192 is then removed from contact with the structural layer 130 and the spacing layer 132.

Referring to FIG. 12, the structural layer 130 and the spacing layer 132, when laminated together by the internal adhesive layer 212, form a structure shown generally at 216, which may be referred to as a “micromechanical structure”. As explained above, in the embodiment shown, due to alignment of the structural layer 130 and the spacing layer 132 in the micromechanical structure 216, the proximal conduit portions 162 and 164 of the structural layer 130 align with the distal conduit portions 188 and 190, respectively, of the spacing layer 132. Thus, in this embodiment, the proximal conduit portion 162 aligns with the distal conduit portion 188 to form a conduit, shown generally at 218, in the micromechanical structure 216. Similarly, the proximal conduit portion 164 aligns with the distal conduit portion 190 to form a conduit, shown generally at 220, in the micromechanical structure 216. In alternative embodiments, the proximal and distal portions may only partially align to form the conduits, or may not align at all. In the fully assembled MEMS structure 128, the conduits 218 and 220 may provide access to electrodes for external wire bonding, as explained further below.

When the structural layer 130 and the spacing layer 132 are laminated together in the micromechanical structure 216, the space 170 of the spacing layer 132 is open to a membrane portion 222 of the structural layer 130. The membrane portion 222 thus has a greater freedom of motion than other portions of the structural layer 130, which are directly attached (laminated) to the spacing layer 132. Furthermore, in some embodiments, the spacing layer 132 may have a much greater thickness than the structural layer 130, and, as a result, the spacing layer 132 may be significantly more rigid than the structural layer 130. In such embodiments, the micromechanical structure 216 may thus have a considerably lower rigidity in a region of the space 170 and the membrane portion 222, where only the (less rigid) structural layer 130 is present, as compared to other regions of the micromechanical structure 216, where both the structural layer 130 and the (more rigid) spacing layer 132 are present. Due to the greater freedom of motion and lower rigidity, the space 170 and the membrane portion 222 effectively define a “structural component” of the micromechanical structure 216.

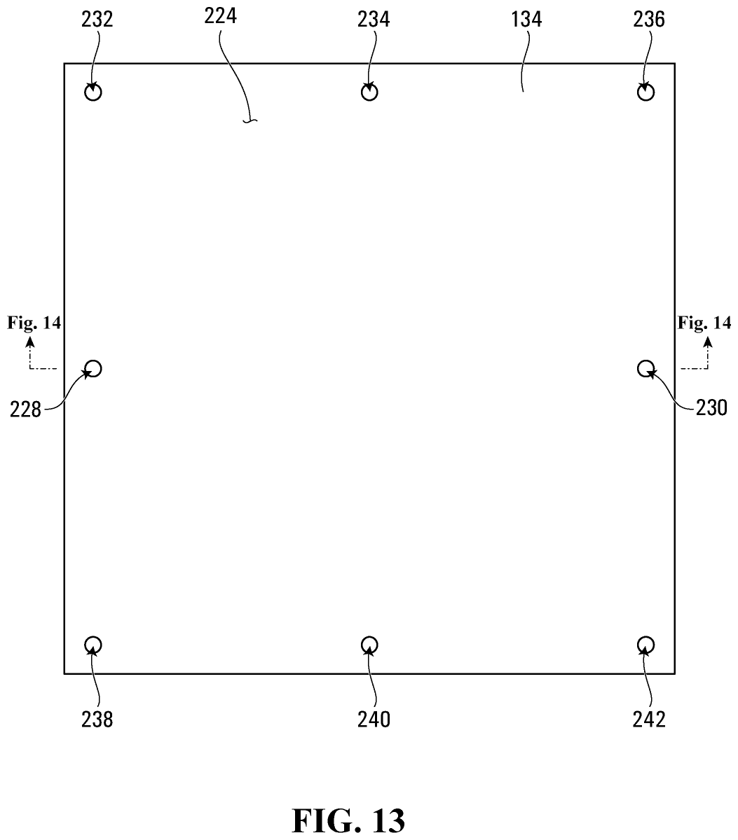

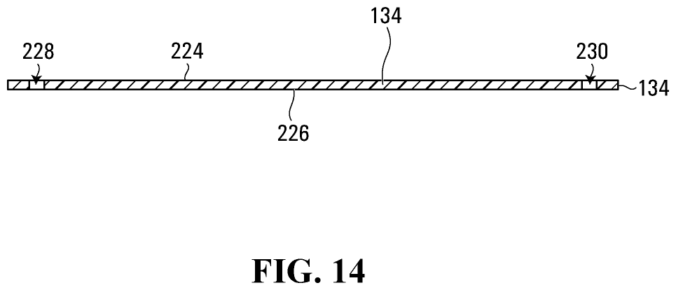

Referring now to FIGS. 1, 13, and 14, at 110, the piezoelectric layer 134 is provided and includes a surface 224 and a surface 226 opposite the surface 224. The piezoelectric layer 134 is ablated using laser micromachining to remove portions of the piezoelectric layer 134 to produce alignment openings, shown generally at 228, 230, 232, 234, 236, 238, 240, and 242, in the piezoelectric layer 134.

In some embodiments, the piezoelectric layer 134 may include polyvinylidene difluoride (PVDF). Additionally or alternatively, the piezoelectric layer 134 may include polyvinylidene fluoride-trifluoroethylene (PVDF-TrFe), or other piezoelectric polymer compounds. In some embodiments, the piezoelectric layer 134 may have a thickness of less than 20 microns. For example, the piezoelectric layer 134 may have a thickness of about 15 microns.

In order to provide the piezoelectric layer 134 with electrodes, the intermediate conductive layer 136 and the outer conductive layer 138 are selectively deposited onto the piezoelectric layer 134 using shadow masks.

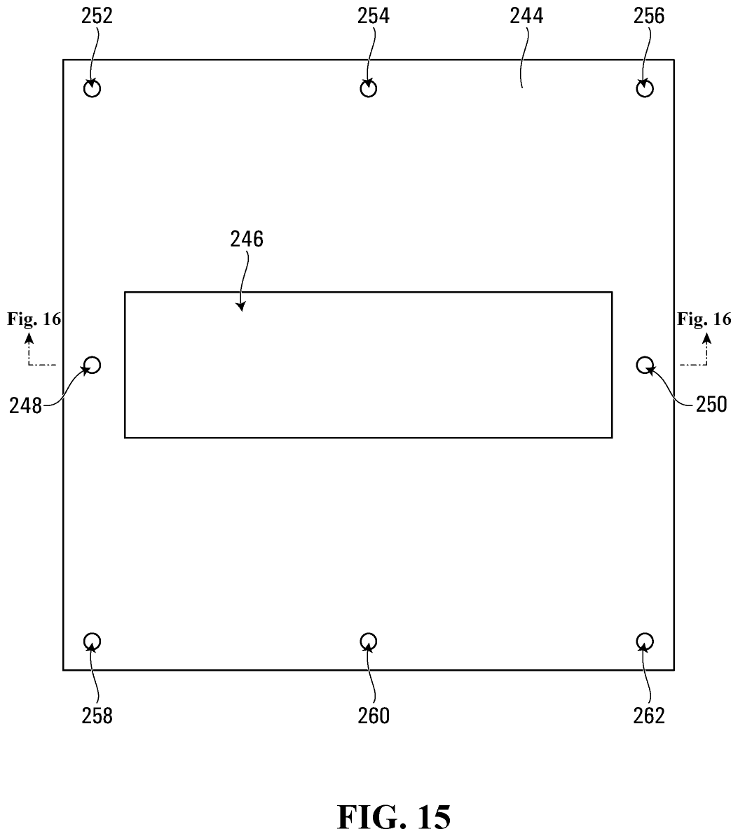

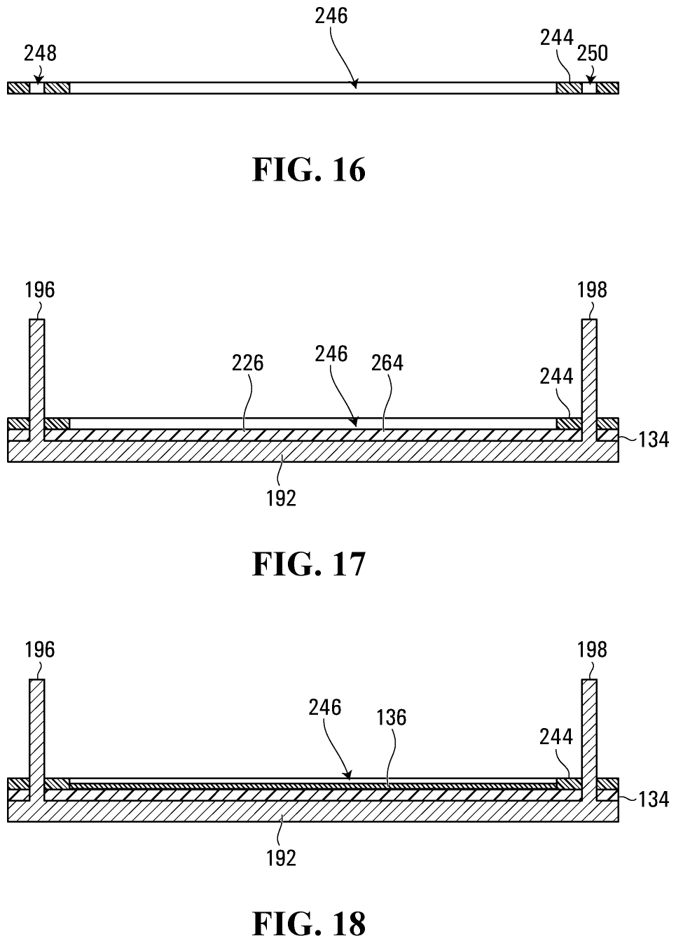

Referring now to FIGS. 1, 15, and 16, at 112, an intermediate shadow mask 244 is provided and is ablated using laser micromachining to remove portions of the intermediate shadow mask 244 to produce an intermediate shadow mask opening, shown generally at 246, and alignment openings, shown generally at 248, 250, 252, 254, 256, 258, 260, and 262, in the intermediate shadow mask 244.

In some embodiments, the intermediate shadow mask 244 may include a polymer, such as, for example, polyimide. Additionally or alternatively, the intermediate shadow mask 244 may include one or more of glass, silicon, and metal. In some embodiments, the intermediate shadow mask 244 may have a thickness of less than 200 microns. For example, the intermediate shadow mask 244 may have a thickness of about 150 microns.

Referring to FIGS. 1, 17, and 18, at 114, the intermediate conductive layer 136 is deposited onto the piezoelectric layer 134. First, as shown in FIG. 17, the piezoelectric layer 134 is overlayed with the alignment reference board 192 such that the surface 224 of the piezoelectric layer 134 contacts the surface 194 of the alignment reference board 192, the surface 226 of the piezoelectric layer 134 remains exposed, the alignment post 196 is positioned through the alignment opening 230, the alignment post 198 is positioned through the alignment opening 228, the alignment post 200 is positioned through the alignment opening 236, the alignment post 202 is positioned through the alignment opening 234, the alignment post 204 is positioned through the alignment opening 232, the alignment post 206 is positioned through the alignment opening 242, the alignment post 208 is positioned through the alignment opening 240, and the alignment post 210 is positioned through the alignment opening 238.

Next, still referring to FIG. 17, the intermediate shadow mask 244 is overlayed with the piezoelectric layer 134 such that the intermediate shadow mask 244 contacts the surface 226 of the piezoelectric layer 134, the alignment post 196 is positioned through the alignment opening 248, the alignment post 198 is positioned through the alignment opening 250, the alignment post 200 is positioned through the alignment opening 252, the alignment post 202 is positioned through the alignment opening 254, the alignment post 204 is positioned through the alignment opening 256, the alignment post 206 is positioned through the alignment opening 258, the alignment post 208 is positioned through the alignment opening 260, and the alignment post 210 is positioned through the alignment opening 262.

In the embodiment shown, when the intermediate shadow mask 244 is overlayed and aligned with the piezoelectric layer 134 as shown in FIG. 17, the intermediate shadow mask 244 covers and thus masks most of the surface 226 of the piezoelectric layer 134. However, a portion 264 of the surface 226 remains exposed within the intermediate shadow mask opening 246. This exposed portion 264 is the only portion of the surface 226 onto which the intermediate conductive layer 136 is to be deposited. Specifically, as shown in FIG. 18, the intermediate conductive layer 136 is deposited through the intermediate shadow mask opening 246 onto the exposed portion 264 of the surface 226, while the intermediate shadow mask 244 prevents deposition of the intermediate conductive layer 136 onto other portions of the surface 226. This approach of depositing the intermediate conductive layer 136 onto only the exposed portion 264 of the surface 226 may be referred to as “selective deposition”. Once the intermediate conductive layer 136 has been deposited onto the piezoelectric layer 134, the alignment reference board 192 and the intermediate shadow mask 244 are removed from contact with the piezoelectric layer 134.

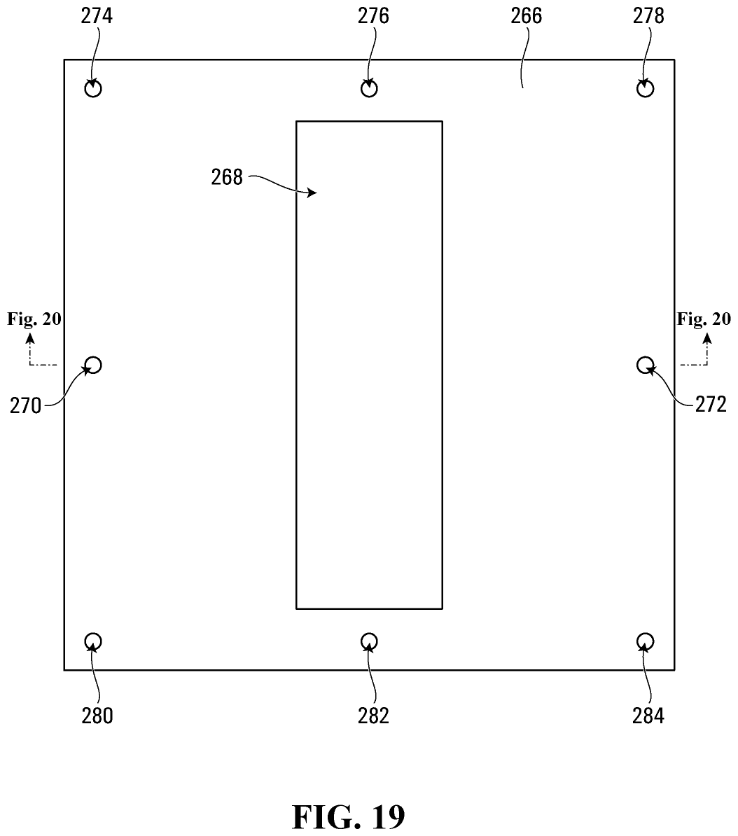

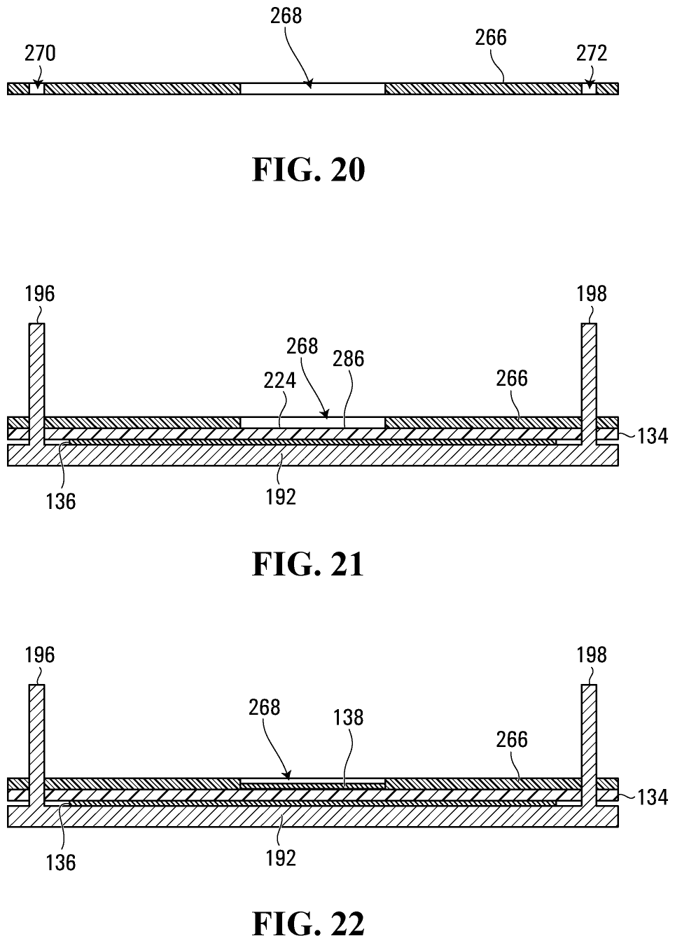

Referring now to FIGS. 1, 19, and 20, at 116, an outer shadow mask 266 is provided and is ablated using laser micromachining to remove portions of the outer shadow mask 266 to produce an outer shadow mask opening, shown generally at 268, and alignment openings, shown generally at 270, 272, 274, 276, 278, 280, 282, and 284, in the outer shadow mask 266.

In some embodiments, the outer shadow mask 266 may include a polymer, such as, for example, polyimide. Additionally or alternatively, the outer shadow mask 266 may include one or more of glass, silicon, and metal. In some embodiments, the outer shadow mask 266 may have a thickness of less than 200 microns. For example, the outer shadow mask 266 may have a thickness of about 150 microns.

Referring to FIGS. 1, 21, and 22, at 118, the outer conductive layer 138 is deposited onto the piezoelectric layer 134. First, as shown in FIG. 21, the piezoelectric layer 134, with the intermediate conductive layer 136 attached to the surface 226, is overlayed with the alignment reference board 192 such that the intermediate conductive layer 136 contacts the surface 194 of the alignment reference board 192, the surface 224 of the piezoelectric layer 134 remains exposed, the alignment post 196 is positioned through the alignment opening 228, the alignment post 198 is positioned through the alignment opening 230, the alignment post 200 is positioned through the alignment opening 232, the alignment post 202 is positioned through the alignment opening 234, the alignment post 204 is positioned through the alignment opening 236, the alignment post 206 is positioned through the alignment opening 238, the alignment post 208 is positioned through the alignment opening 240, and the alignment post 210 is positioned through the alignment opening 242.

Next, still referring to FIG. 21, the outer shadow mask 266 is overlayed with the piezoelectric layer 134 such that the outer shadow mask 266 contacts the surface 224 of the piezoelectric layer 134, the alignment post 196 is positioned through the alignment opening 270, the alignment post 198 is positioned through the alignment opening 272, the alignment post 200 is positioned through the alignment opening 274, the alignment post 202 is positioned through the alignment opening 276, the alignment post 204 is positioned through the alignment opening 278, the alignment post 206 is positioned through the alignment opening 280, the alignment post 208 is positioned through the alignment opening 282, and the alignment post 210 is positioned through the alignment opening 284.

In the embodiment shown, when the outer shadow mask 266 is overlayed and aligned with the piezoelectric layer 134 as shown in FIG. 21, the outer shadow mask 266 covers and thus masks most of the surface 224 of the piezoelectric layer 134. However, a portion 286 of the surface 224 remains exposed within the outer shadow mask opening 268. This exposed portion 286 is the only portion of the surface 224 onto which the outer conductive layer 138 is to be deposited. Specifically, as shown in FIG. 22, the outer conductive layer 138 is deposited through the outer shadow mask opening 268 onto the exposed portion 286 of the surface 224, while the outer shadow mask 266 prevents deposition of the outer conductive layer 138 onto other portions of the surface 224. Once the outer conductive layer 138 has been deposited onto the piezoelectric layer 134, the alignment reference board 192 and the outer shadow mask 266 are removed from contact with the piezoelectric layer 134.

In some embodiments, the intermediate conductive layer 136 and the outer conductive layer 138 may include a metal, such as, for example, aluminum. In some embodiments, the intermediate conductive layer 136 and the outer conductive layer 138 may include an aluminum nano film.

In some embodiments, physical vapor deposition (PVD) techniques may be used to deposit the intermediate conductive layer 136 and the outer conductive layer 138 onto the piezoelectric layer 134. For example, the intermediate conductive layer 136 and the outer conductive layer 138 may be deposited using electron-beam (e-beam) evaporation.

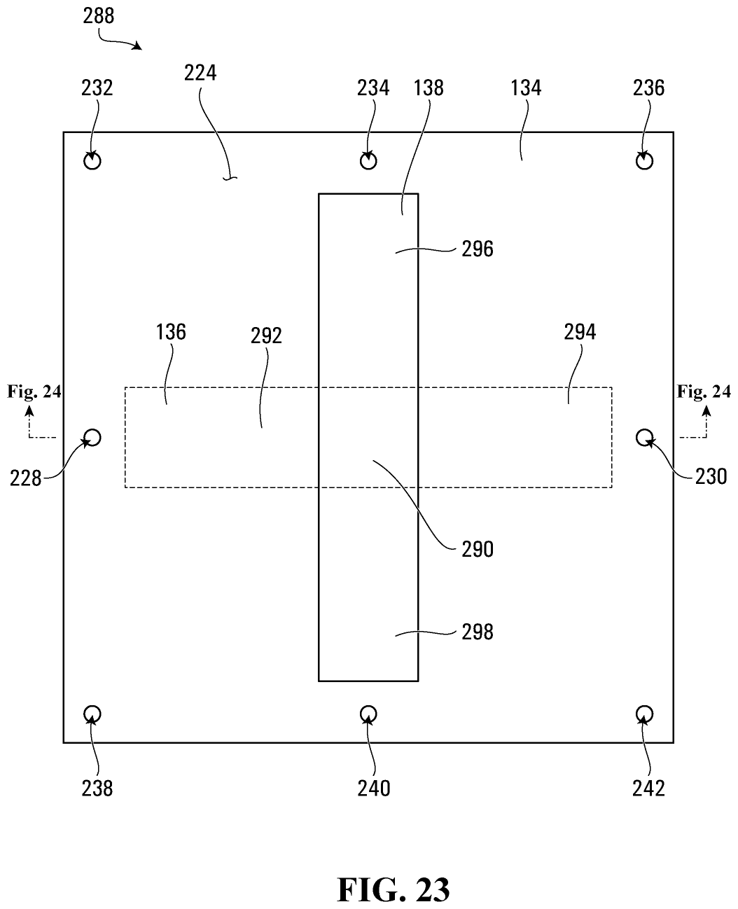

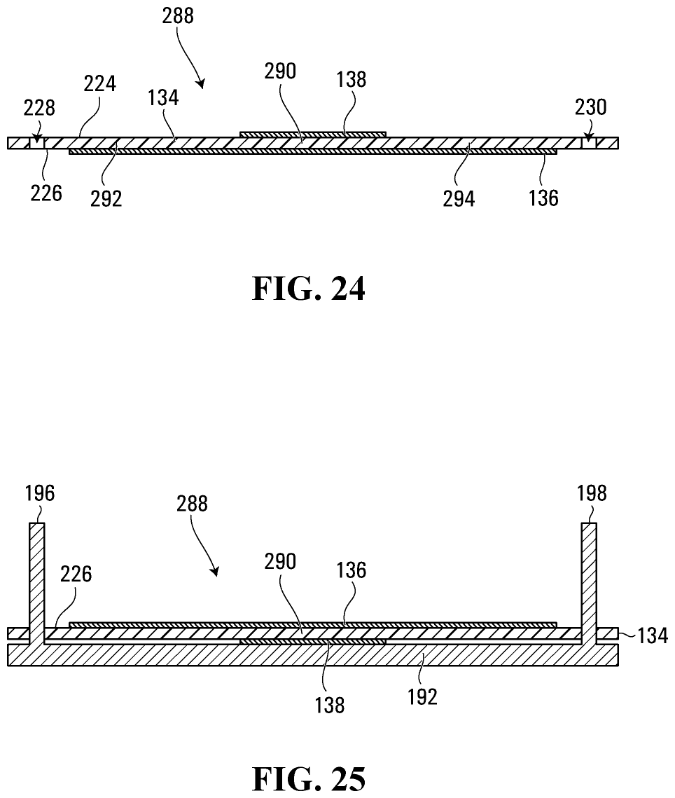

Referring to FIGS. 23 and 24, the piezoelectric layer 134, along with the attached intermediate conductive layer 136 and outer conductive layer 138, form a structure shown generally at 288, which may be referred to as an “electromechanical layer”. In the electromechanical layer 288, the intermediate conductive layer 136 and the outer conductive layer 138 may function as a pair of electrodes, separated by the piezoelectric layer 134, to enable electromechanical coupling for the MEMS structure 128. When an electrical voltage is applied between the intermediate conductive layer 136 (a first electrode) and the outer conductive layer 138 (a second electrode), mechanical stress is generated in the piezoelectric layer 134 due to the (inverse) piezoelectric effect, thus transforming electrical energy into mechanical energy. This transformation enables actuation of the MEMS structure 128. Similarly, when a mechanical force is applied to the piezoelectric layer 134, an electrical displacement charge is generated between the first and second electrodes due to the direct piezoelectric effect, thus transforming mechanical energy into electrical energy. This transformation enables sensory functions of the MEMS structure 128.

In the embodiment shown, due to the selective deposition of the intermediate conductive layer 136 and the outer conductive layer 138 onto the piezoelectric layer 134, the electromechanical layer 288 includes a region 290 where both the intermediate conductive layer 136 and the outer conductive layer 138 are present, as well as regions 292 and 294 where only the intermediate conductive layer 136 is present, and regions 296 and 298 where only the outer conductive layer 138 is present. The region 290, with both the intermediate conductive layer 136 (the first electrode) and the outer conductive layer 138 (the second electrode), may enable electromechanical coupling, as described above. This region may also be referred to as a “moving region”. The regions 292, 294, 296, and 298, which may also be referred to as “contact regions”, may be used for wire bonding the electromechanical layer 288 to an external circuit (not shown). Specifically, in the embodiment shown, the contact regions 292 and 294 are used for wire bonding the intermediate conductive layer 136, while the contact regions 296 and 298 are used for wire bonding the outer conductive layer 138.

Wire bonding may involve application of large forces, exposure to organic solvents, and/or high temperatures. As such, the piezoelectric layer 134 may be damaged or even breached during the wire bonding process. If the piezoelectric layer 134 is breached by a wire during wire bonding, the wire may contact both the intermediate conductive layer 136 and outer conductive layer 138 (i.e., both the first and second electrode), thus causing a short circuit. However, wire bonding exclusively in the contact regions 292, 294, 296, and 298, where only one of the intermediate conductive layer 136 or the outer conductive layer 138 is present, may minimize the risk of short circuitry: even if the piezoelectric layer 134 is breached by a wire in one of these regions, the wire may not contact both the intermediate conductive layer 136 and outer conductive layer 138.

Referring now to FIGS. 1 and 25 to 27, at 120, the electromechanical layer 288 is laminated to the micromechanical structure 216. First, as shown in FIG. 25, the electromechanical layer 288 is overlayed with the alignment reference board 192 such that the outer conductive layer 138 contacts the surface 194 of the alignment reference board 192, the intermediate conductive layer 136 and portions of the surface 226 of the piezoelectric layer 134 remain exposed, the alignment post 196 is positioned through the alignment opening 230, the alignment post 198 is positioned through the alignment opening 228, the alignment post 200 is positioned through the alignment opening 236, the alignment post 202 is positioned through the alignment opening 234, the alignment post 204 is positioned through the alignment opening 232, the alignment post 206 is positioned through the alignment opening 242, the alignment post 208 is positioned through the alignment opening 240, and the alignment post 210 is positioned through the alignment opening 238.

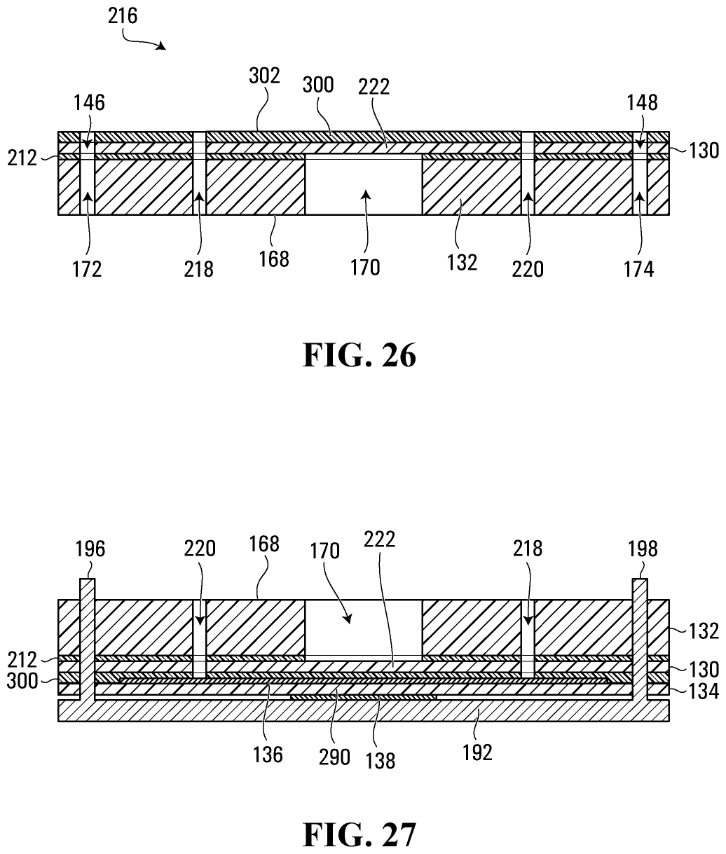

Next, as shown in FIG. 26, a primary adhesive layer 300 is deposited onto the surface 142 of the structural layer 130. The primary adhesive layer 300 includes a surface 302 which remains exposed when the primary adhesive layer 300 is deposited onto the structural layer 130. In some embodiments, the primary adhesive layer 300 may be deposited onto the structural layer 130 using spin-coating. In other embodiments, the primary adhesive layer 300 may be deposited onto the structural layer 130 using ultrasonic coating. In some embodiments, the primary adhesive layer 300 may include an adhesive epoxy such as, for example, SU-8 photoresist.

Finally, as shown in FIG. 27, the primary adhesive layer 300, with the micromechanical structure 216 attached, is overlayed with the electromechanical layer 288 and the alignment reference board 192 such that the surface 302 of the primary adhesive layer 300 contacts the intermediate conductive layer 136 and the surface 226 of the piezoelectric layer 134, the alignment post 196 is positioned through the alignment openings 148 and 174, the alignment post 198 is positioned through the alignment openings 146 and 172, the alignment post 200 is positioned through the alignment openings 154 and 180, the alignment post 202 is positioned through the alignment openings 152 and 178, the alignment post 204 is positioned through the alignment openings 150 and 176, the alignment post 206 is positioned through the alignment openings 160 and 186, the alignment post 208 is positioned through the alignment openings 158 and 184, and the alignment post 210 is positioned through the alignment openings 156 and 182. Contact between the primary adhesive layer 300 and the intermediate conductive layer 136 and piezoelectric layer 134 may cause the primary adhesive layer 300 to adhere to the intermediate conductive layer 136 and piezoelectric layer 134, thus adhesively laminating the structural layer 130 of the micromechanical structure 216 to the intermediate conductive layer 136 and piezoelectric layer 134 of the electromechanical layer 288. The alignment reference board 192 is then removed from contact with the micromechanical structure 216 and the electromechanical layer 288.

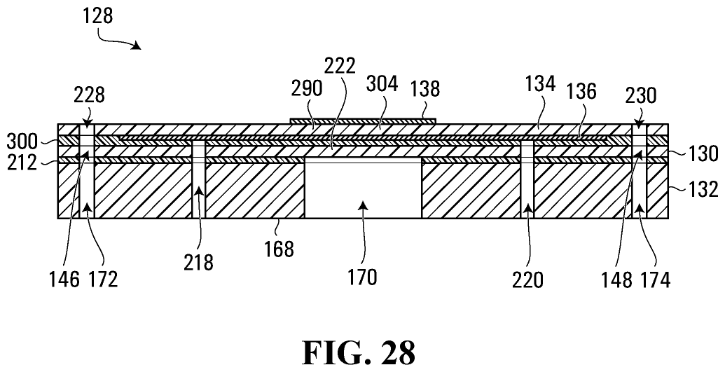

Referring to FIG. 28, when the electromechanical layer 288 is laminated to the micromechanical structure 216, the moving region 290 of the electromechanical layer 288 includes an actuatable portion which is directly overlayed with the structural component of the micromechanical structure 216 defined by the membrane portion 222 of the structural layer 130 and the space 170 of the spacing layer 132. The membrane portion 222 of the structural layer 130 and the actuatable portion 304 of the moving region 290 of the electromechanical layer 288 effectively define the location where electromechanical coupling for the MEMS structure 128 is effective and apparent (i.e., can be easily perceived through the motion of the membrane).

The micromechanical structure 216 and the electromechanical layer 288 may possess inadequate mechanical properties, such as rigidity and strength, for an intended application of the MEMS structure 128. In the method of this embodiment, the MEMS structure 128 is further reinforced using the support frame 140.

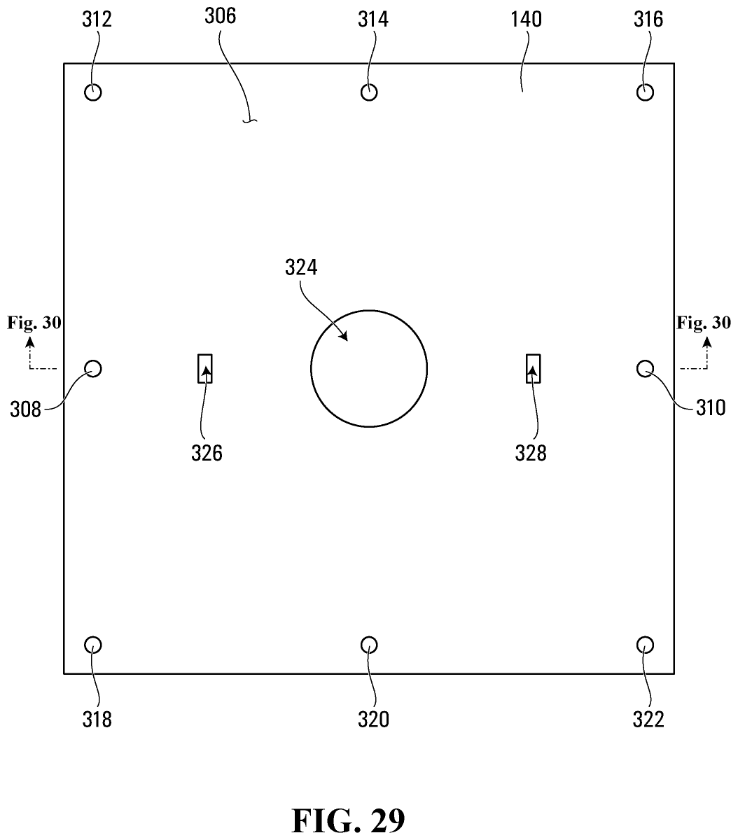

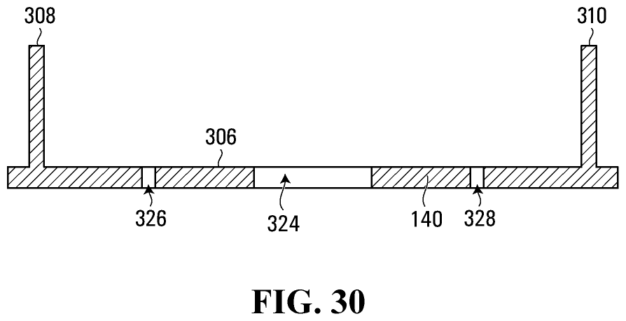

Referring now to FIGS. 1, 29, and 30, at 122, the support frame 140 is manufactured using 3D printing. The support frame 140 includes a surface 306 and support posts 308, 310, 312, 314, 316, 318, 320, and 322. Additionally, the support frame 140 defines a space extension 324 and conduit extensions 326 and 328. Although in this embodiment 3D printing is used to manufacture the support frame 140, in other embodiments, other methods may be used. For example, in some other embodiments, the support frame 140 may be manufactured using computer numerical controlled (CNC) machining.

In the embodiment shown, the support posts 308, 310, 312, 314, 316, 318, 320, and 322 are located in positions on the support frame 140 that correspond directly to positions of the alignment posts 196, 198, 200, 202, 204, 206, 208, and 210, respectively, on the alignment reference board 192. Thus, for example, the micromechanical structure 216 and the electromechanical layer 288 may be overlayed with the support frame 140 as they were with the alignment reference board 192.

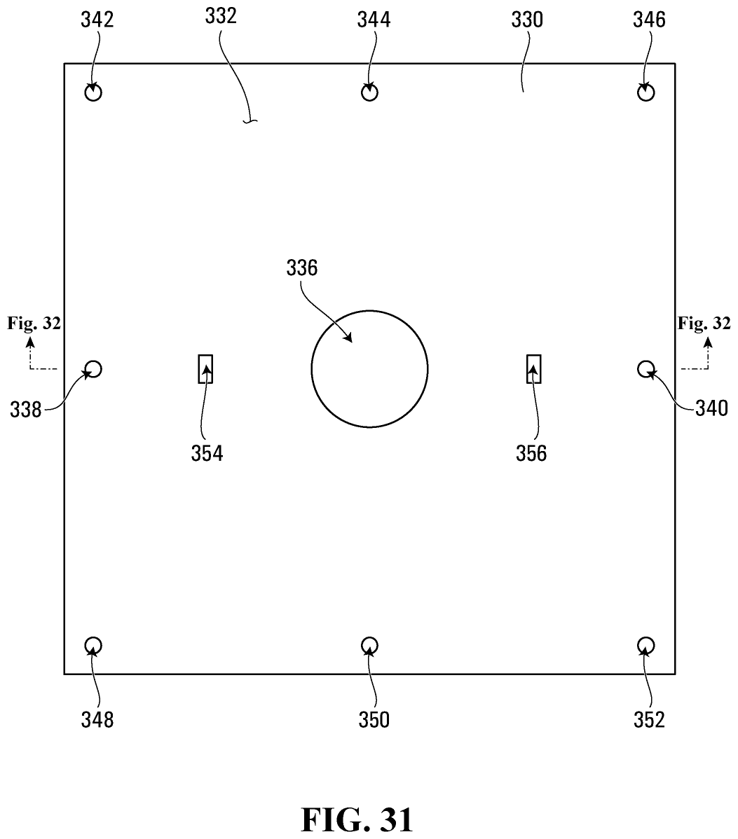

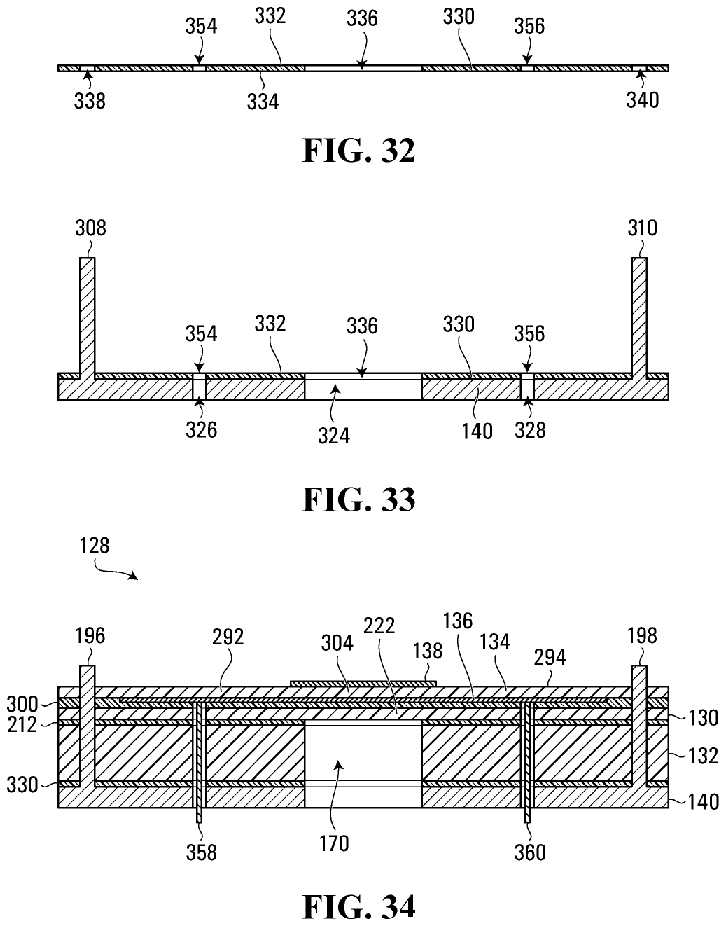

Referring to FIGS. 1, 31, and 32, at 124, a support frame adhesive layer 330 is provided and includes a surface 332 and a surface 334 opposite the surface 332. The support frame adhesive layer 330 is ablated using laser micromachining to remove portions of the support frame adhesive layer 330 to produce a space extension, shown generally at 336, alignment openings, shown generally at 338, 340, 342, 344, 346, 348, 350 and 352, and conduit extensions, shown generally at 354 and 356, in the support frame adhesive layer 330. In some embodiments, the support frame adhesive layer 330 may include double-sided transfer tape.

Referring to FIGS. 1, 2, and 33, at 126, the micromechanical structure 216, with the electromechanical layer 288 attached, is laminated to the support frame 140. First, as shown in FIG. 33, the support frame adhesive layer 330 is overlayed with the support frame 140 such that the surface 334 of the support frame adhesive layer 330 contacts the surface 306 of the support frame 140, the surface 332 of the support frame adhesive layer 330 remains exposed, the support post 308 is positioned through the alignment opening 338, the support post 310 is positioned through the alignment opening 340, the support post 312 is positioned through the alignment opening 342, the support post 314 is positioned through the alignment opening 344, the support post 316 is positioned through the alignment opening 346, the support post 318 is positioned through the alignment opening 348, the support post 320 is positioned through the alignment opening 350, and the support post 322 is positioned through the alignment opening 352. Contact between the support frame adhesive layer 330 and the support frame 140 may cause the support frame adhesive layer 330 to adhere to the support frame 140. When the support frame adhesive layer 330 is overlayed with the support frame 140 as describe above and shown in FIG. 33, the space extension 324 of the support frame 140 aligns with the space extension 336 of the support frame adhesive layer 330 and the conduit extensions 326 and 328 of the support frame 140 align with the conduit extensions 354 and 356, respectively, of the support frame adhesive layer 330.

Next, as shown in FIG. 2, the micromechanical structure 216, with the electromechanical layer 288 attached, is overlayed with the support frame adhesive layer 330 such that the surface 168 of the spacing layer 132 contacts the surface 332 of the support frame adhesive layer 330, the support post 308 is positioned through the alignment openings 172, 146, and 228, the support post 310 is positioned through the alignment openings 174, 148, and 230, the support post 312 is positioned through the alignment openings 176, 150, and 232, the support post 314 is positioned through the alignment openings 178, 152, and 234, the support post 316 is positioned through the alignment openings 180, 154, and 236, the support post 318 is positioned through the alignment openings 182, 156, and 240, the support post 320 is positioned through the alignment openings 184, 158, and 242, and the support post 322 is positioned through the alignment openings 186, 160, and 244. Contact between the support frame adhesive layer 330 and the spacing layer 132 may cause the support frame adhesive layer 330 to adhere to the spacing layer 132, thus adhesively laminating the micromechanical structure 216 to the support frame 140 and producing the fully assembled MEMS structure 128.

Referring now to FIGS. 2 and 33, when the micromechanical structure 216 and the support frame 140 are laminated together to form the MEMS structure 128, the space extensions 324 and 336 of the support frame 140 and the support frame adhesive layer 330, respectively, align with the space 170 of the spacing layer 132. As such, the space extensions 324 and 336 effectively extend the space 170 through the support frame 140 and the support frame adhesive layer 330. Similarly, the conduit extensions 326 and 354 align with and thus effectively extend the conduit 218, and the conduit extensions 328 and 356 align with and thus effectively extend the conduit 220.

As mentioned above, the MEMS structure 128 can be connected to an external circuit (not shown) by wire bonding the intermediate conductive layer 136 (the first electrode) and the outer conductive layer 138 (the second electrode) to the external circuit. In the embodiment shown, the outer conductive layer 138 is exposed and is thus easily accessible for wire bonding. However, the intermediate conductive layer 138 is located within the MEMS structure 128 and can only be accessed through the conduits 218 and 220.

Referring to FIGS. 2, 23, and 34, in order to wire bond the outer conductive layer 138 to the external circuit, wires (not shown) are attached to the outer conductive layer 138 at the contact regions 296 and 298. In order to wire bond the intermediate conductive layer 136 to the external circuit, wires 358 and 360 are positioned through conduits 218 and 220, respectively, and are attached to the intermediate conductive layer 136 at the contact regions 292 and 294, respectively.

Of course, the embodiment of FIGS. 1 to 34 is an example only, and alternative embodiments may vary. For example, alternative embodiments may involve different numbers or arrangements of the alignment/support posts and corresponding alignment openings. As specific examples, some alternative embodiments may involve only three alignment/support posts and corresponding alignment openings, while other alternative embodiments may involve more than three alignment/support posts and corresponding alignment openings. In some alternative embodiments, one or more of the structural layer 130, spacing layer 132, and piezoelectric layer 134 may not have the same number or positioning of alignment openings as the other layers, or may not include alignment openings at all. In other alternative embodiments, the MEMS structure 128 may not include the support frame 140 and the support frame adhesive layer 330. In yet other alternative embodiments, the support frame adhesive layer 330 may be deposited onto the support frame 140 using spin-coating. In such embodiments, the support frame adhesive layer 330 may include polypropylene carbonate.

Still other alternative embodiments may involve carrying out the steps of FIG. 1 in a different order than that shown, or may not include all of the steps of FIG. 1, or may include additional steps. For example, some alternative embodiments may involve carrying out the lamination steps 108, 120, and 126 in a different order than that depicted in FIG. 1. As a more specific example, in some alternative embodiments, the electromechanical layer 288 may be laminated to the structural layer 130 before the structural layer 130, with the electromechanical layer 288 attached, is laminated to the spacing layer 132.

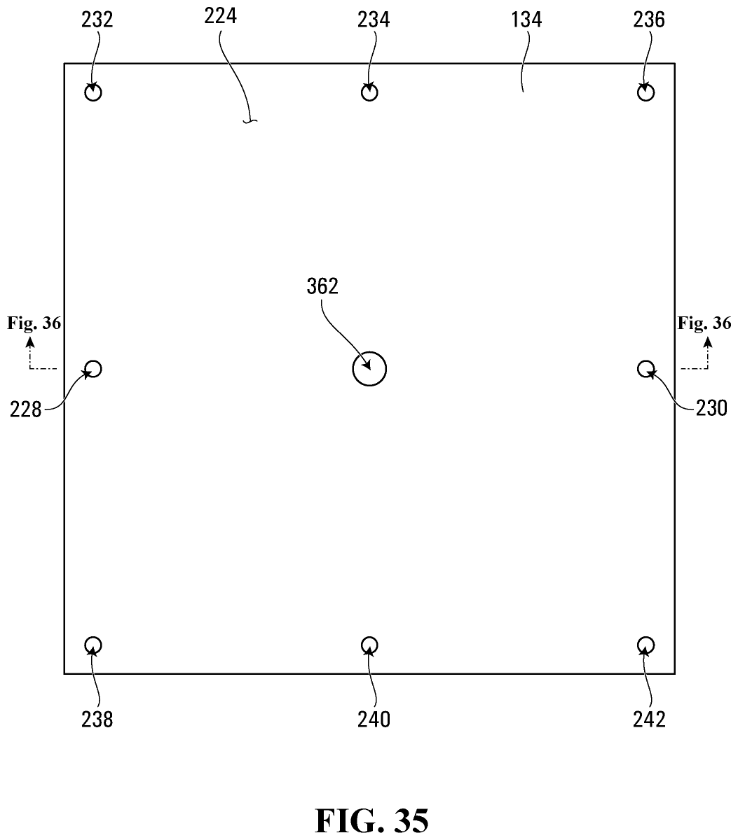

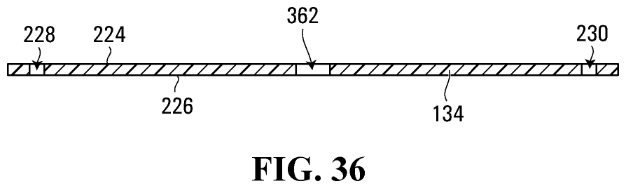

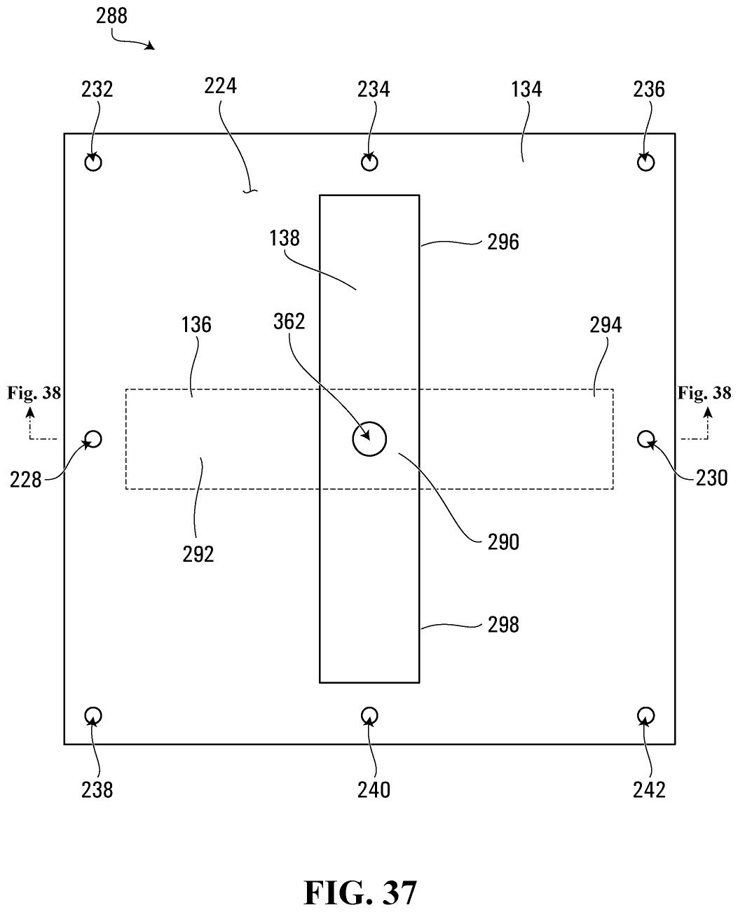

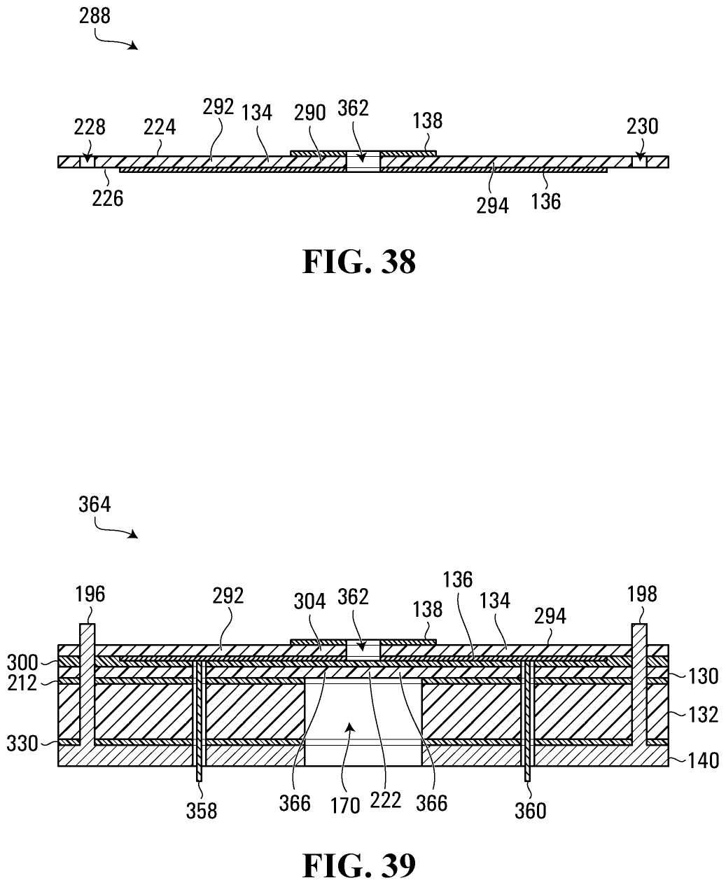

Some alternative embodiments may include ablating the piezoelectric layer 134 to produce additional openings in the moving region 290 of the electromechanical layer 288. For example, referring to FIGS. 1 and 35 to 39, one such alternative embodiment may be identical to the embodiment of FIGS. 1 to 34 above, except in that when the piezoelectric layer 134 is ablated at 110, laser micromachining is further used to remove an additional portion of the piezoelectric layer 134 to produce a circular opening shown generally at 362, as shown in FIGS. 35 and 36. Due to its position in the moving region 290, the circular opening 362 will extend to the intermediate conductive layer 136 and the outer conductive layer 138 when, at 114 and 118, respectively, these layers are deposited onto the piezoelectric layer 134, as shown in FIGS. 37 and 38. Further, as shown in FIG. 39, a MEMS structure, shown generally at 364, fabricated according to this alternative embodiment includes the circular opening 362 positioned coaxial with the space 170.

In the embodiment shown in FIG. 39, the circular opening 362 has a radius that is less than the radius of the space 170. As such, in the MEMS structure 364, the piezoelectric layer 134 overlays with only with an edge portion 366 of the membrane portion 222 of the structural layer 130. The edge portion 366 may also be referred to as a “clamping edge”. As described further below, such partial overlay of the piezoelectric layer 134 with the structural layer 130 at the clamping edge 366 may improve process reproducibility of MEMS structure fabrication, without reducing actuation efficiency of the MEMS structures produced.

The following non-limiting examples are illustrative of embodiments of the present disclosure.

### Example 1

### Fabrication and Characterization of Piezoelectric MEMS Transducers

In this example, piezoelectric MEMS transducers based on fully-clamped circular membranes were fabricated in accordance with an embodiment. Fabrication of the MEMS transducers of this example generally followed the processing steps of the flowchart 100 and included 3D printing of an alignment reference board and a support frame, laser micromachining of a structural layer, a spacing layer, a piezoelectric layer, a support frame adhesive layer, an intermediate shadow mask, and an outer shadow mask, and deposition of an intermediate conductive layer and an outer conductive layer onto the piezoelectric layer.

A 25 micron (μm) thick Kapton™ polyimide film (Dupont™, USA/Cole-Parmer™ Canada) was used for the structural layer, a 150 μm thick Kapton™ polyimide film (Dupont™, USA/Cole-Parmer™, Canada) was used for the spacing layer and the intermediate and outer shadow masks, and a 15 μm thick piezoelectric PVDF-TrFE film was used for the piezoelectric layer. The structural layer, spacing layer, piezoelectric layer, and intermediate and outer shadow masks were laser micromachined using an Oxford Lasers micromachining system. For micromachining of the structural layer, the system settings were: 100% intensity, 3 repeats, and 0.5 millimeters/second (mm/s) laser moving speed. For micromachining of the spacing layer and the intermediate and outer shadow masks, the system settings were: 100% intensity, 12 repeats, and 0.5 mm/s laser moving speed. For micromachining of the piezoelectric layer, the system settings were: 50% intensity, 2 repeats, and 2 mm/s laser moving speed.

An aluminum nano film was used for the intermediate and outer conductive layers. For each conductive layer, a DeeDirector load-lock e-beam PVD system was used to deposit 100 nm aluminum films onto the piezoelectric layer, with a current of 190-210 milliAmps (mA) and a deposition rate of 3.9 Amps/second (A/s).

The structural, spacing, and piezoelectric layers were laminated together using SU-8 2000.5 photoresist (Kayaku™ Advanced Materials, USA). This photoresist can be effective as an adhesive epoxy for lamination, even without ultraviolet radiation (UV) exposure. The SU-8 photoresist was spin-coated onto the spacing and structural layers using a Ni-Lo 5 Vacuum spin-coater, with a spin coating speed of 2500 rotations per minute (rpm) and a resulting coating thickness of 300-500 nanometers (nm). Adhesive lamination was carried out in a Fortex Engineering Dry Film Laminator Model 304, with a lamination speed of 1 mm/s and a lamination temperature of 80° C.

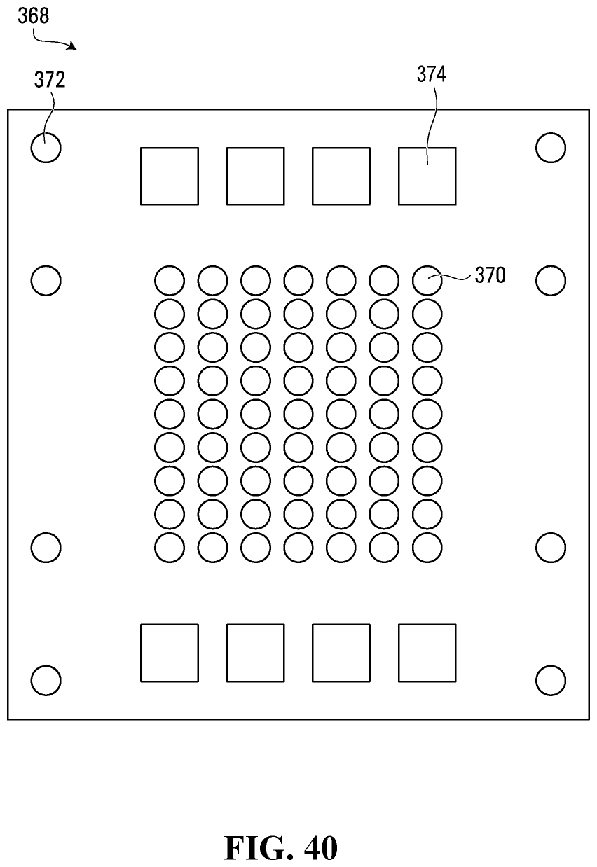

Referring to FIG. 40, a laser micromachining mask for the spacing layer is shown generally at 368, and includes white lines corresponding to a designed path for the laser cut. The mask 368 includes spacing hole cutouts, such as spacing hole cutout 370, alignment opening cutouts, such as alignment opening cutout 372, and distal conduit portion cutouts, such as distal conduit portion cutout 374. The spacing hole cutouts are arranged in a 9-by-7 array, with a distance of 100 μm between each row and a distance of 750 μm between each column. Each spacing hole cutout has a radius of 750 μm. Each alignment opening cutout has a radius of 750 μm. Each distal conduit portion cutout has dimensions of 3 mm by 3 mm.

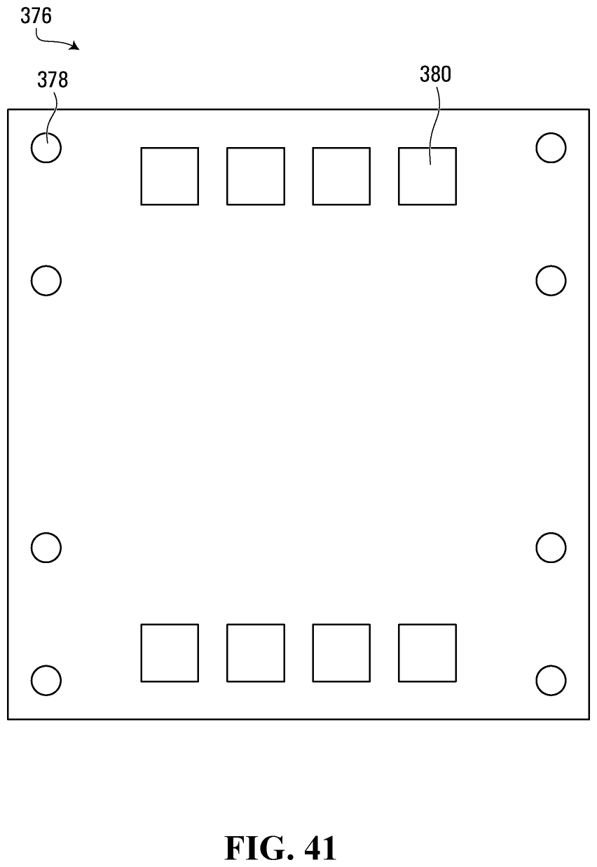

Referring to FIG. 41, a laser micromachining mask for the structural layer is shown generally at 376, and includes white lines corresponding to a designed path for the laser cut. The mask 376 includes alignment opening cutouts, such as alignment opening cutout 378, and proximal conduit portion cutouts, such as proximal conduit portion cutout 380. Each alignment opening cutout has a radius of 750 μm. Each proximal conduit portion cutout has dimensions of 3 mm by 3 mm.

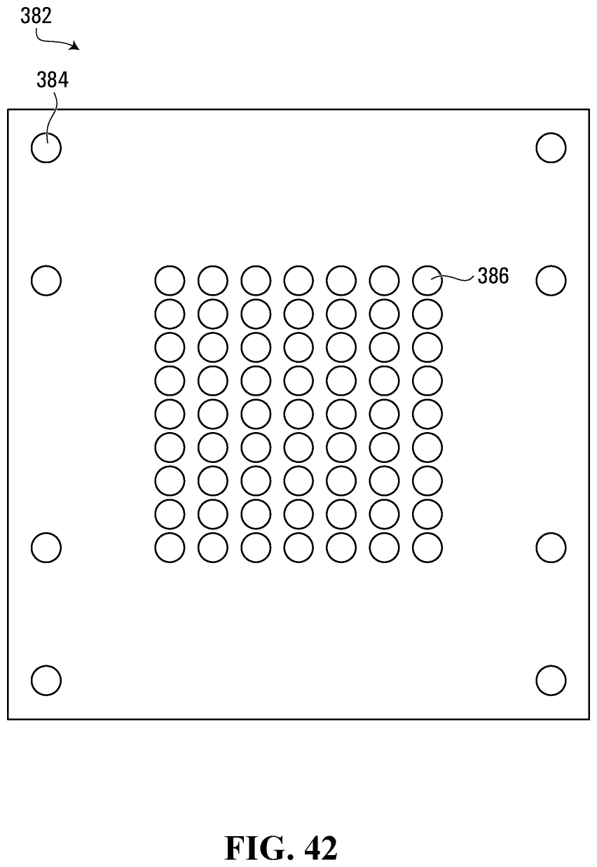

Referring to FIG. 42, a laser micromachining mask for the piezoelectric layer is shown generally at 382, and includes white lines corresponding to a designed path for the laser cut. The mask 382 includes alignment opening cutouts, such as alignment opening cutout 384, and circular hole cutouts, such as circular hole cutout 386. Each alignment opening cutout has a radius of 750 μm. Each circular hole cutout has a radius of 600 μm.

Referring now to FIGS. 40, 41, and 42, each of the masks 368, 376, and 382 has overall dimensions of 32.5 mm (vertical) by 30 mm (horizontal). The positions of the alignment opening cutouts on each of the masks 368, 376, and 382 correspond. Similarly, the positions of the distal conduit portion cutouts on the mask 368 correspond to the positions of the proximal conduit portion cutouts on the mask 376, and the positions of the spacing hole cutouts of the mask 368 correspond to the positions of the circular hole cutouts of the mask 382.

The spacing, structural, and piezoelectric layers were laser micromachined using the masks 368, 376, and 382, respectively. Notably, the spacing holes cutouts of the mask 368 produced corresponding spacing holes in the spacing layer, and the circular hole cutouts of the mask 382 produced corresponding circular holes in the piezoelectric layer. The spacing and structural layers were then laminated together to produce movable membranes in the structural layer at each of the spacing holes in the spacing layer—that is, a 9-by-7 array of fully-clamped circular movable membranes. After depositing the intermediate and outer conductive layers onto the piezoelectric layer, the piezoelectric layer was laminated to the structural layer to produce a MEMS transducer at each movable membrane—that is, a 9-by-7 array of MEMS transducers.

Due to the corresponding positions of the spacing hole cutouts of the mask 368 and the circular hole cutouts of the mask 382, each circular hole in the piezoelectric layer was aligned with a corresponding spacing hole in the spacing layer and thus a corresponding movable membrane in the structural layer. Further, due to the differing radii of the spacing hole cutouts (750 μm) and the circular hole cutouts (600 μm), the piezoelectric layer only partially overlayed with each movable membrane, around a clamping edge. Such a structural configuration helps in maintaining a high process reproducibility, without reducing actuation efficiency.

The central part of a fully-clamped circular membrane may experience the most significant mechanical responses. If there is any structural variation in this region among different circular membranes with the same dimension designs, their performance may become non-uniform. Off-the-shelf piezoelectric films have a significant thickness variation. This variation may be around 5% to 10%. If the piezoelectric layer were to fully cover an entire movable membrane, it may result in non-uniform performance among individual elements of the array of movable membranes. Meanwhile, covering only the clamping edge of the movable membrane with the piezoelectric layer may not significantly impact electromechanical coupling efficiency, as explained below.

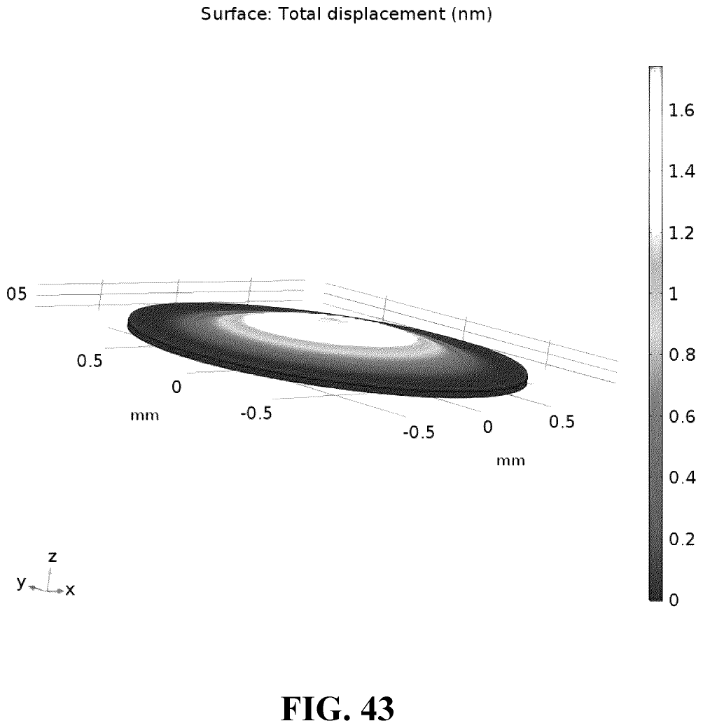

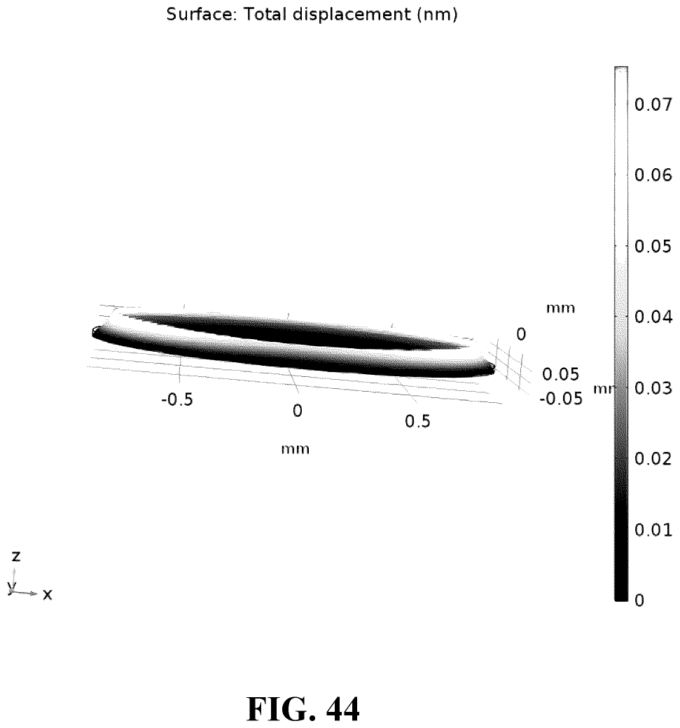

A finite element analysis in COMSOL Multiphysics™ was conducted to examine if partial piezoelectric layer overlay of a movable membrane will reduce electromechanical coupling efficiency. The subject of the simulation was a circular polyimide membrane with a radius of 500 μm and a thickness of 25 μm. The analysis simulated an electrical-to-mechanical coupling (piezoelectric actuation) for two piezoelectric layer arrangements: 1) full overlay with the membrane, and 2) overlay only over a clamping edge region (20% of a membrane radius). The finite element analysis assumed that the piezoelectric layer had a thickness of 15 μm, i.e., the thickness of the off-the-shelf piezoelectric film used in reality. Both piezoelectric layer arrangements were assumed to use 1 volt (V) of direct current (DC) voltage for actuation. The mechanical deformation of the membrane under this applied voltage was compared. The finite element analysis results for the clamping edge overlay arrangement are shown in FIG. 43, and the finite element analysis results for the full overlay arrangement are shown in FIG. 44. As shown in FIG. 43, when the piezoelectric layer only covers the clamping edge of the circular membrane, deformation across the membrane has a typical Gaussian profile. Such a profile matches with a general case of an external load being applied to such a structure. Maximum deformation occurs around a central part of the membrane, with a magnitude around 1.6 nm. In contrast, as shown in FIG. 44, when the piezoelectric layer fully covers the membrane, a deformation profile of the membrane is abnormal. Maximum deformation happens at an edge of the membrane. Meanwhile, deformation magnitude is about 20 times smaller. This simulation result indicates that not fully covering the circular membrane with the piezoelectric layers may be beneficial to piezoelectric-based electromechanical coupling.

The MEMS transducers of this example were characterized and tested using optical inspection, laser Doppler vibrometer measurements, and electrical impedance measurements. Optical inspection was carried out using an optical microscope and was used to check the surface of the device obtained after microfabrication. Laser Doppler vibrometer measurements were carried out using a Polytec MSA-500 Micro System Analyzer (U_{ACPP}=3 V; frequency scanning range between 0 to 400 kilohertz [kHz]), and were used to examine mechanical resonance of the transducers under electrical actuation, to assess process reproducibility. Electrical impedance measurements were carried out using an Agilent 4294A impedance analyzer (U_{ACPP}=1 V; frequency scanning range between 22 Hz and 55 kHz), and were used to assess whether the transducers had a bi-directional electromechanical coupling interface.

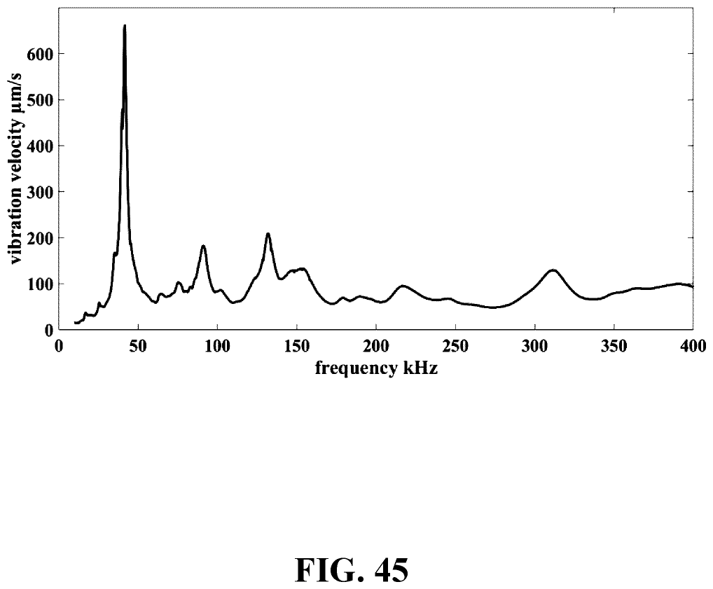

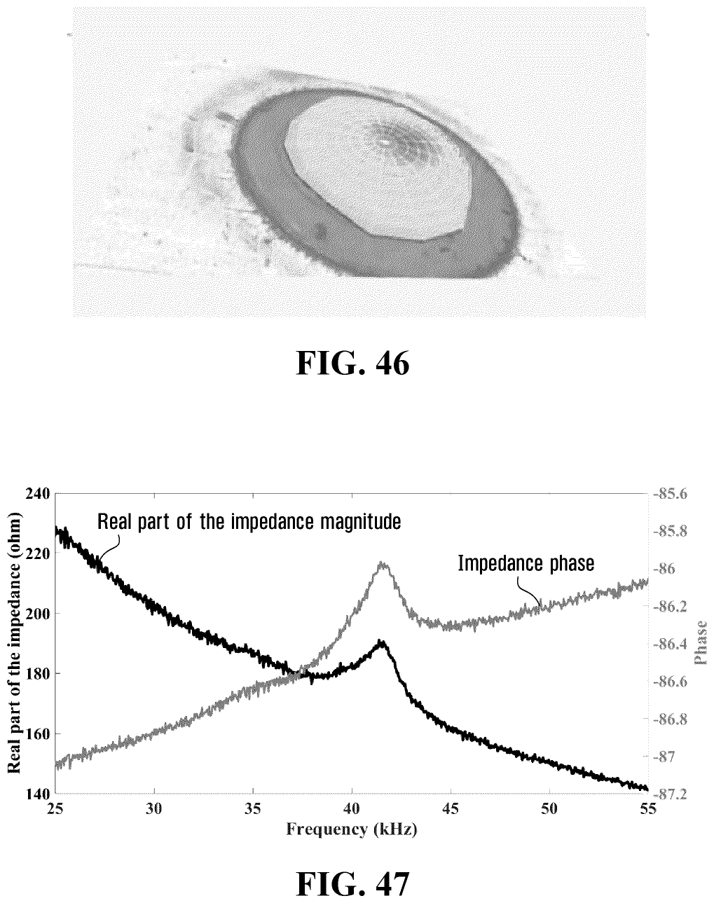

Results of the laser Doppler vibrometer measurements are presented in FIGS. 45 and 46. FIG. 45 shows an average of the mechanical resonance frequency response spectrums of 54 of the elements of the MEMS transducer array of this example. FIG. 46 shows the measured modal shape for the peak response on the mechanical resonance spectrum. In FIG. 45, the peak response of the mechanical resonance has a typical resonance response profile. A Gaussian profile is a representative modal shape for the fundamental resonant mode of a fully-clamped circular membrane. This measurement result may indicate that the lamination-based assembly of different component layers of the MEMS transducers is robust. That is, this manufacturing method has not caused any critical defect in the micromechanical structural layers. The standard deviation of the 54 different elements' resonance was 2.12%. Such a low standard deviation indicates that the MEMS fabrication technique of this embodiment may be quite reproducible and robust. In this respect, the quality of this technique is comparable with that of polymer MEMS microfabrication techniques based on surface micromachining processes, which may have a corresponding standard deviation around 1.5% to 3%.

Results of the electrical impedance measurements are presented in FIG. 47. A typical electrical impedance measurement process of a MEMS device electrically actuates the MEMS device using sine-wave signals over a user-defined frequency band. The actuation results in a forced vibration of the MEMS device. The impedance magnitude and phase are monitored to examine a bi-directional energy transition. Energy from the electrical domain supports the MEMS device's mechanical vibration. The frequency-energy status of the MEMS device's vibration is reflected in the electrical domain. When the MEMS device is vibrating around its mechanical resonant frequency, both its vibration magnitude and velocity approach the maximum value. The maximized kinetic and elastic energy requires extra energy from the electrical domain. If this extra energy dissipation is observable on the impedance measurement result, it means the mechanical energy status of the MEMS devices can be well-presented in the electrical domain and that the measured MEMS device has an effective bi-directional coupling interface. In FIG. 47, peaks show up on both the impedance magnitude and phase measurement results. The peaks are located around the mechanical resonant frequency measured by laser Doppler vibrometry, as described above and shown in FIG. 45. Hence, the results of the electrical impedance measurements indicate that the MEMS transducer array manufactured in this example has a bi-directional electromechanical coupling interface.

The AC signal available in an impedance analyzer generally has a small magnitude, typically around 1 V. If multiple MEMS devices with the same design are measured simultaneously, a measurable bi-directional electromechanical coupling interface under such a minor excitation requires a uniform and significant resonant frequency and magnitude for all devices. Such resonance requires the fabrication process for the MEMS devices to be highly reproducible and the structural material to have limited built-in damping. In this respect, FIG. 47 effectively supports the quality and feasibility of the fabrication technique of this example.

### Example 2

### Fabrication of Piezoelectric MEMS Mass Sensors

In this example, piezoelectric MEMS mass sensors based on fully-clamped circular membranes were fabricated in accordance with an embodiment. MEMS resonating mass sensors detect a loaded mass through the resonant frequency shift due to external mass load. A mathematical explanation for its working principle is briefly provided here.

The general expression of a mechanical structure's resonant frequency is:

$$f = \frac{1}{2 π} \sqrt{\frac{{k}_{eq}}{{m}_{eq}}} \qquad ( 1 )$$

In Equation (1), f is the resonant frequency, k_{eq} is the equivalent spring constant for the resonance, and m_{eq} is the equivalent mass for the corresponding resonant mode.

A mass load added to the sensor body does not significantly change k_{eq}. Its influence on the equivalent mass is more significant. The expression of a mass sensor's resonant frequency with mass load is:

$$f ( m ) = \frac{1}{2 π} \sqrt{\frac{{k}_{eq}}{{m}_{0} + m}} \qquad ( 2 )$$

In Equation (2), m₀ is the initial equivalent mass with zero mass load, m is the load mass. Generally, m is significantly smaller than m₀. Equation (2) can therefore be linearized through a Taylor expansion at m=0:

$$\{ \begin{matrix}f ( 0 ) = \frac{1}{2 π} \sqrt{\frac{{k}_{eq}}{{m}_{0}}} \\ \frac{df}{dm} = - \frac{1}{2} \frac{{k}_{eq}^{0.5}}{{( {m}_{0} + m )}^{- 1.5}} \\ \frac{df}{dm} {\vert}_{m = 0} = - \frac{1}{2} \frac{f ( 0 )}{{m}_{0}} \\ f ( m ) \approx f ( 0 ) - \frac{1}{2} \frac{f ( 0 )}{{m}_{0}} m\end{matrix} \qquad ( 3 )$$

In Equation (3), f(0) is the initial resonant frequency without any mass load. As inferable from Equation (3), with proper design and microfabrication methods, MEMS resonating mass sensors can have extremely high sensitivity. For example, mass sensors made with silicic materials may achieve a sensitivity that can sense mass variations at picogram (10⁻¹² gram) or even at femtogram (10⁻¹⁵ gram) levels. Such a high sensitivity makes these mass sensors powerful platforms for chemical or biomass detection.

However, there are also some issues faced by silicon-based MEMS resonating mass sensors in real applications. For example, a common way to design silicic MEMS resonating mass sensors is to make them single-clamped cantilevers. Such a structure has trouble interacting with a liquid environment, primarily due to its operation in an overdamped mode, that deteriorates the resonant behavior (sensing the resonant frequency). However, many types of biomass or chemicals are present in solutions. Without proper isolation, if a single-clamped cantilever interacts directly with a liquid sample, either its performance will be degraded due to the significant damping, or it will suffer from structural failures due to capillary forces. Known solutions to address this issue have been overly complex. An alternative technique, described in the embodiment below, avoids the complete immersion of the resonant device in liquid, and rather lets a droplet of the sample be sensed on a vibrating area of the resonator. If the droplet volume dosage is well controlled, the measurement can reveal information about the sample composition.

The method of this example for fabricating a MEMS mass sensor may be relatively simple and rapid. As for the transducers of Example 1 above, fabrication of the MEMS mass sensors of this example generally followed the processing steps of the flowchart 100 and included 3D printing of an alignment reference board and a support frame, laser micromachining of a structural layer, a spacing layer, a piezoelectric layer, a support frame adhesive layer, an intermediate shadow mask, and an outer shadow mask, and deposition of an intermediate conductive layer and an outer conductive layer onto the piezoelectric layer.

A 12 μm thick Kapton™ polyimide film (Dupont™, USA/Cole-Parmer™, Canada) was used for the structural layer, a 150 μm thick Kapton™ polyimide film (Dupont™, USA/Cole-Parmer™, Canada) was used for the spacing layer and the intermediate and outer shadow masks, and a 15 μm thick piezoelectric PVDF-TrFE film was used for the piezoelectric layer. The structural layer, spacing layer, piezoelectric layer, and intermediate and outer shadow masks were laser micromachined using an Oxford Lasers micromachining system. For micromachining of the structural layer, the system settings were: 100% intensity, 3 repeats, and 0.5 mm/s laser moving speed. For micromachining of the spacing layer and the intermediate and outer shadow masks, the system settings were: 100% intensity, 12 repeats, and 0.5 mm/s laser moving speed. For micromachining of the piezoelectric layer, the system settings were: 50% intensity, 2 repeats, and 2 mm/s laser moving speed.

An aluminum nano film was used for the intermediate and outer conductive layers. For each conductive layer, a DeeDirector load-lock e-beam PVD system was used to deposit 100 nm aluminum films onto the piezoelectric layer, with a current of 190-210 mA and a deposition rate of 3.9 A/s.

The structural, spacing, and piezoelectric layers were laminated together using SU-8 2000.5 photoresist (Kayaku™ Advanced Materials, USA). This photoresist can be effective as an adhesive epoxy for lamination, even without ultraviolet radiation (UV) exposure. The SU-8 photoresist was spin-coated onto the spacing and structural layers using a Ni-Lo 5 Vacuum spin-coater, with a spin coating speed of 2500 rpm and a resulting coating thickness of 300-500 nm. Adhesive lamination was carried out in a Fortex Engineering Dry Film Laminator Model 304, with a lamination speed of 1 mm/s and a lamination temperature of 80° C.

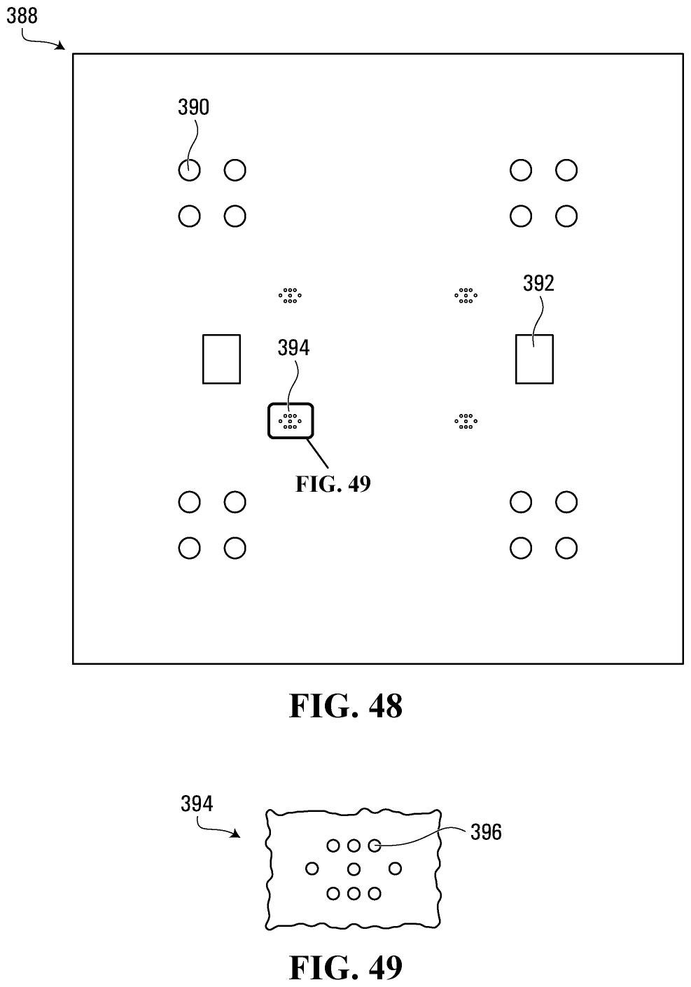

Referring to FIGS. 48 and 49, a laser micromachining mask for the structural layer is shown generally at 388, and includes white lines corresponding to a designed path for the laser cut. The mask 388 includes alignment opening cutouts, such as alignment opening cutout 390, proximal conduit portion cutouts, such as proximal conduit portion cutout 392, and alignment marker cutouts, such as alignment marker cutout 394. Each alignment opening cutout has a radius of 500 μm. Each proximal conduit portion cutout has dimensions of 2 mm by 2.6 mm. Each alignment marker cutout includes alignment marker opening cutouts, such as alignment marker opening cutout 396. Each alignment marker opening cutout has a radius of 25 μm. During laser micromachining, the alignment marker cutouts produce corresponding alignment markers in the structural layer. These markers are used to help accurately load external mass onto a central part of the mass sensors.

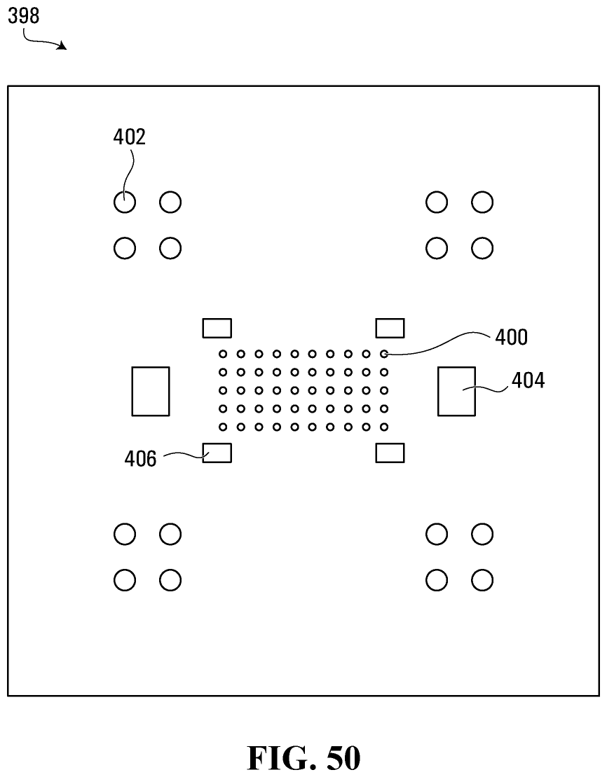

Referring to FIG. 50, a laser micromachining mask for the spacing layer is shown generally at 398, and includes white lines corresponding to a designed path for the laser cut. The mask 398 includes spacing hole cutouts, such as spacing hole cutout 400, alignment opening cutouts, such as alignment opening cutout 402, distal conduit portion cutouts, such as distal conduit portion cutout 404, and alignment window cutouts, such as alignment window cutout 406. The spacing hole cutouts are arranged in a 10-by-5 array. Each spacing hole cutout has a radius of 175 μm. Each alignment opening cutout has a radius of 500 μm. Each distal conduit portion cutout has dimensions of 2 mm by 2.6 mm. Each alignment window cutout has dimensions of 1.3 mm by 0.8 mm. During laser micromachining, the alignment window cutouts produce corresponding alignment windows in the spacing layer, which provide access to the alignment markers of the structural layer.

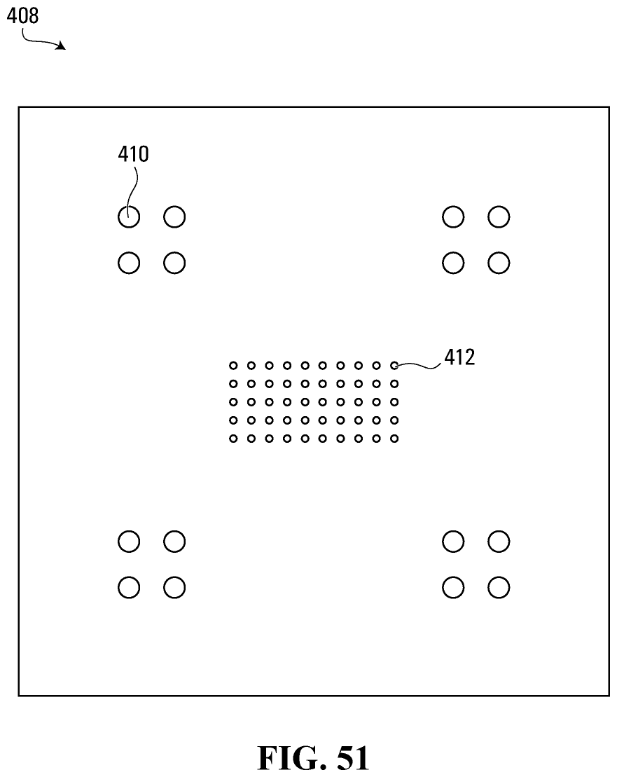

Referring to FIG. 51, a laser micromachining mask for the piezoelectric layer is shown generally at 408, and includes white lines corresponding to a designed path for the laser cut. The mask 408 includes alignment opening cutouts, such as alignment opening cutout 410, and circular hole cutouts, such as circular hole cutout 412. Each alignment opening cutout has a radius of 500 μm. Each circular hole cutout has a radius of 100 μm.

Referring now to FIGS. 48 to 51, each of the masks 388, 398, and 408 has overall dimensions of 33 mm by 33 mm. The positions of the alignment opening cutouts on each of the masks 388, 398, and 408 correspond. Similarly, the positions of the proximal conduit portion cutouts on the mask 388 correspond to the positions of the distal conduit portion cutouts on the mask 398, and the positions of the spacing hole cutouts of the mask 398 correspond to the positions of the circular hole cutouts of the mask 408.

The structural, spacing, and piezoelectric layers were laser micromachined using the masks 388, 398, and 408, respectively. Notably, the spacing holes cutouts of the mask 398 produced corresponding spacing holes in the spacing layer, and the circular hole cutouts of the mask 408 produced corresponding circular holes in the piezoelectric layer. The spacing and structural layers were then laminated together to produce movable membranes in the structural layer at each of the spacing holes in the spacing layer—that is, a 10-by-5 array of fully-clamped circular movable membranes. After depositing the intermediate and outer conductive layers onto the piezoelectric layer, the piezoelectric layer was laminated to the structural layer to produce a MEMS mass sensor at each movable membrane—that is, a 10-by-5 array of MEMS mass sensors.

Due to the corresponding positions of the spacing hole cutouts of the mask 398 and the circular hole cutouts of the mask 408, each circular hole in the piezoelectric layer was aligned with a corresponding spacing hole in the spacing layer and thus a corresponding movable membrane in the structural layer. Further, due to the differing radii of the spacing hole cutouts (175 μm) and the circular hole cutouts (100 μm), the piezoelectric layer only partially overlayed with each movable membrane: specifically, in a 75 μm-wide area around a clamping edge of the membrane. As explained above regarding Example 1, this structural configuration helps in maintaining a high process reproducibility, without reducing actuation efficiency.

For the purposes of characterization, two identical arrays of MEMS mass sensors were fabricated and tested. One array (i.e., the “unloaded array”) was not loaded with any mass. The other array (i.e., the “loaded array”) was loaded using an array of SU-8 micropillars (i.e., a mass load) in order to test its performance.

SU-8 2075 was used for the micropillar array. The micropillar array was produced using SU-8 lithography with an Intelligent Micropatterning SF-100 maskless lithography system. Processing parameters for the SU-8 lithography are summarized in Table 1.

TABLE 1
Processing parameters for SU-8 lithography of micropillar array.

| Spin-coating | | | | | Post-exposure | | | |
|---|---|---|---|---|---|---|---|---|
| speed | Soft baking | | 365 nm UV exposure | | baking | | Developing | |
| 1500 RPM | 65° C. | 95° C. | Intensity | Duration | 65° C. | 95° C. | Chemical | Immersion |
| | 3 min | 6 min | 10 mW/cm² | 10 s | 6 min | 3 min | PGMEA | 10 min |

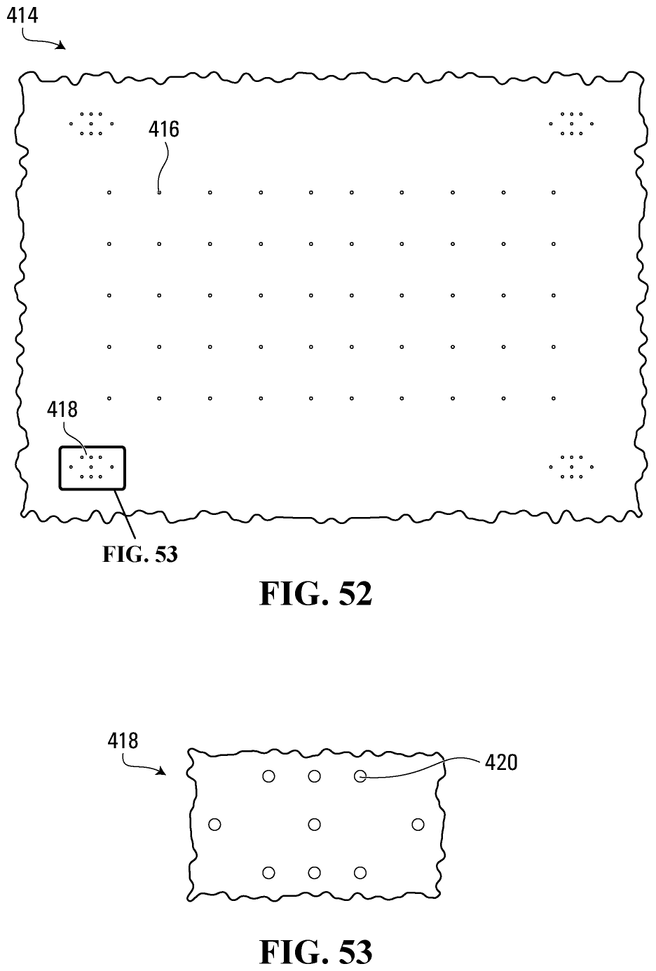

Referring to FIGS. 52 and 53, a lithography mask for the SU-8 micropillar array is shown generally at 414, and includes white patterns corresponding to regions exposed to the lithography process. SU-8 photoresist is a crosslinking-based negative photoresist epoxy. During lithography, polymerization is triggered within the exposed regions. The mask 414 includes circular micropillars, such as circular micropillar 416, and alignment markers, such as alignment marker 418. Each circular micropillar has a radius of 15 μm. The circular micropillars were used to apply the mass load to the MEMS mass sensors of the loaded array. Each alignment marker has dimensions of 1.3 mm by 0.8 mm and includes alignment marker openings, such as alignment marker openings 420. Each alignment marker opening has a radius of 25 μm. During mass loading of the loaded array, the alignment markers of the structural layer were aligned with the alignment markings of the SU-8 micropillar array through the windows of the spacing layer, in order to accurately position each circular micropillar through a corresponding spacing hole of the spacing layer to apply a load to a corresponding movable membrane of the structural layer.

The MEMS mass sensors of this example were characterized and tested using optical inspection and laser Doppler vibrometer measurements. Additionally, prior to testing, the SU-8 micropillar array was characterized using white light interferometry. Optical inspection of the MEMS mass sensors was carried out using an optical microscope and was used to check the surface of the microfabricated devices. Reliable testing of a resonating mass sensor's detection of an external mass load requires both: 1) a relatively accurate estimate of the mass load, and 2) high resolution and high precision mechanical resonating frequency measurements of the mass sensor. White light interferometry of the SU-8 micropillars was carried out using a Polytec MSA-500 Micro System Analyzer, and was used to obtain the physical dimensions of the micropillars, thus making it possible to estimate the applied extra mass load. Laser Doppler vibrometer measurements of the MEMS mass sensors were carried out using a Polytec MSA-500 Micro System Analyzer (U_{ACPP}=5V; frequency: 0 to 1.5 MHz), and were used to obtain optimized resonance measurements, making it possible to characterize the mass sensor's performance reliably.

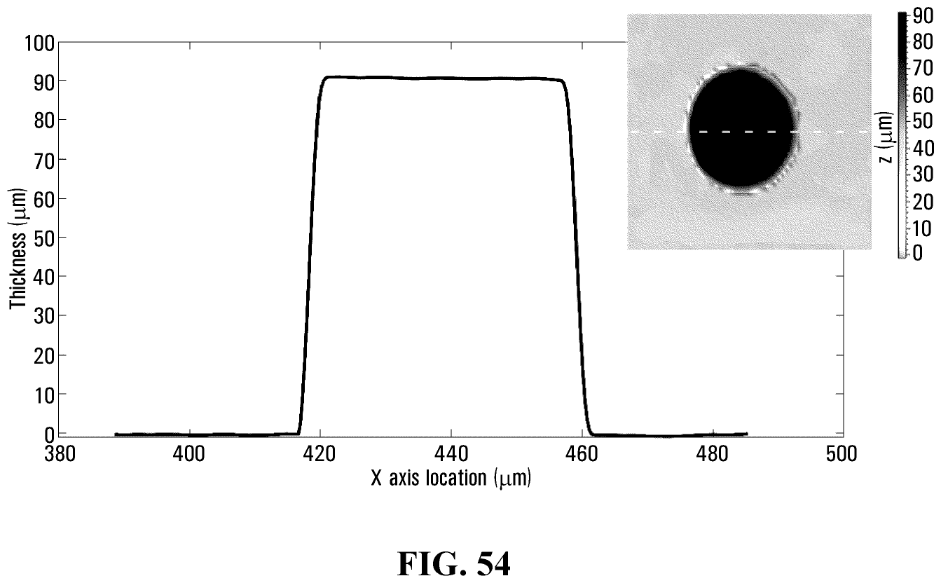

Results of white-light interferometer measurements for a representative SU-8 micropillar are presented in FIG. 54. As shown in FIG. 54, SU-8 lithography resulted in micropillars with a structural thickness of around 90 μm. The representative micropillar has an actual radius around 22 μm. SU-8 2075 is highly viscous. It consists mostly of polymer epoxy and photoinitiator salt. Hence, it is reasonable to directly use SU-8 2075's density, 1230 kg/m³, to estimate the mass load. Based on this density and the measured dimensions of the representative SU-8 micropillar in FIG. 54, the computed mass for a single SU-8 micropillar load was estimated to be around 167 ng.

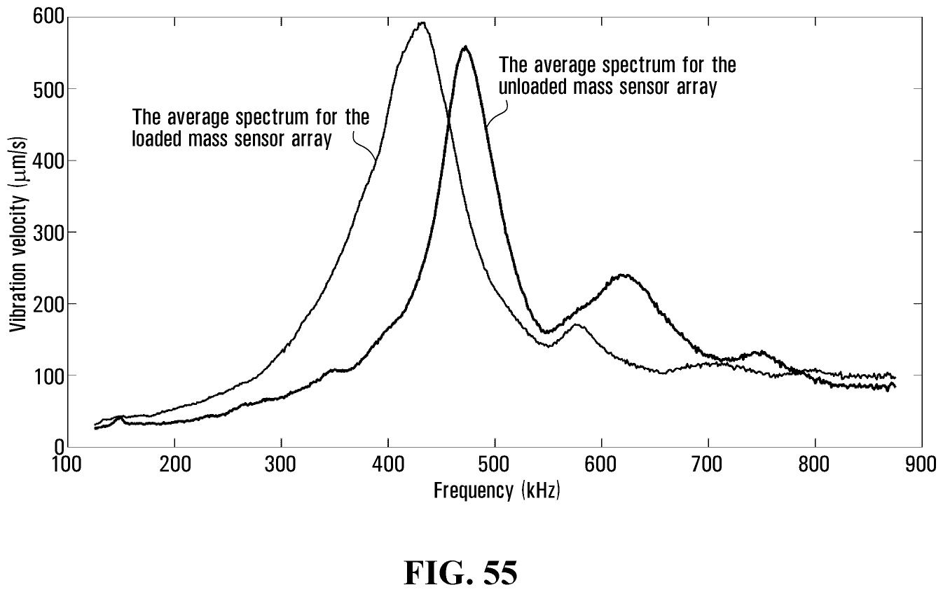

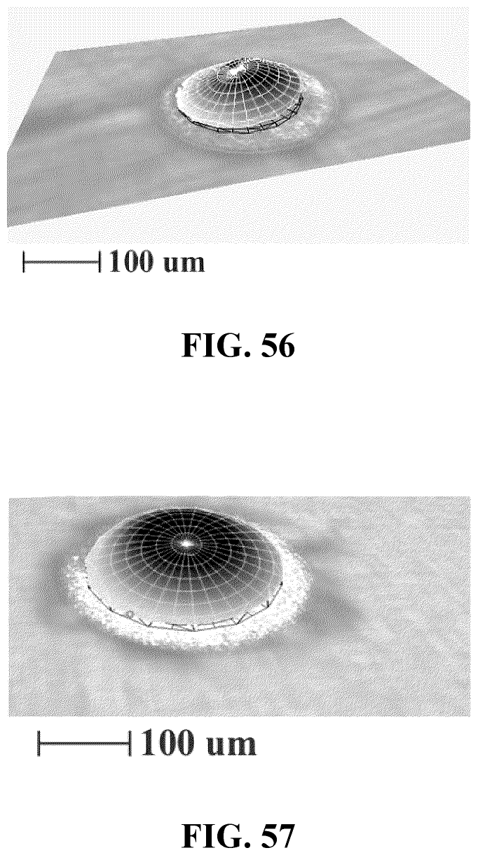

Results of the laser Doppler vibrometer measurements for both the loaded and unloaded arrays are presented in FIGS. 55 to 57. For each of the loaded and unloaded arrays, FIG. 55 shows an average of the measured mechanical resonance frequency response spectrums of all 50 of elements of the array. FIG. 56 shows the measured modal shape for the fundamental resonant mode of the 50 MEMS mass sensors of the loaded array. FIG. 57 shows the measured modal shape for the fundamental resonant mode of the 50 MEMS mass sensors of the unloaded array.

As shown in FIG. 55, the mass sensors of the unloaded array have very uniform mechanical resonance. The average resonant frequency is 473.97 kHz, with a standard deviation of around 1.65%. Such a highly consistent performance indicates that the fabrication method of this embodiment is reproducible and robust. For the mass sensors of the loaded array, the average resonant frequency was 417.24 kHz, with a standard deviation of around 7%. Even though the resonant behavior of the mass sensors appears to become less uniform when the array has been loaded with extra mass, the upper limit of the resonant frequency for the loaded array is only around 450 kHz. In comparison, the lower limit of the resonant frequency for the unloaded array is around 470 kHz. Thus, the loaded and unloaded arrays' mechanical resonant behaviors do not overlap.

In addition, as shown in FIGS. 56 and 57, the modal shapes of the MEMS sensors of the loaded and unloaded arrays have a typical Gaussian profile with a maximum deflection located around a geometric center. Such a profile is the typical profile of the fundamental resonant mode for a fully-clamped circular membrane.

Based on the results shown in FIGS. 55 to 57, the average frequency sensitivity of the polymeric MEMS mass sensors of this example was determined to be 331 Hz/ng, or 0.71 ppm/pg. This sensitivity is comparable to or greater than the sensitivity of many known silicic MEMS mass sensors.

### CONCLUSION

In general, this disclosure provides methods for fabricating MEMS structures involving lamination of an electromechanical layer to a micromechanical structure. These methods may be used, for example, to fabricate membrane-based piezoelectric MEMS devices, and, in particular, polymer-based, thin-film, piezoelectric MEMS membrane actuators. Due to their use of lamination-based assembly, the methods of fabricating MEMS devices described herein may impose fewer limits on device area than polymer surface micromachining, and may also have a lower complexity to scale up for mass production.

As a specific example, the methods of this disclosure may be particularly suitable for producing polymer-based, thin film, circular MEMS resonating mass sensors. Such mass sensors may be especially applicable for detection of biochemical mass, such as pH value detection in human sweat, or pathogen concentration detection in human blood. The detection targets in these application scenarios have total masses at the nanogram or even microgram level. Rather than high sensitivity, the primary concern in such application scenarios is whether the sensing microsystems are disposable, due to biochemical safety concerns. Because of their relative simplicity, the fabrication methods described herein may provide a feasible means of manufacturing disposable MEMS resonating mass sensors for safe, accurate, and rapid biochemical mass detection.

Although specific embodiments have been described and illustrated, such embodiments should be considered illustrative only and not as limiting the invention as construed according to the accompanying claims.

1. A method of fabricating a micro electro-mechanical systems (MEMS) structure, the method comprising:
aligning a first layer of the MEMS structure with a second layer of the MEMS structure by positioning alignment posts through corresponding alignment openings in each of the first layer and the second layer; and
when the alignment posts are positioned through the corresponding alignment openings, laminating the first layer to the second layer.

2. The method of claim 1, wherein positioning the alignment posts through the alignment openings comprises positioning at least one of the alignment posts through a corresponding one of the alignment openings in the first layer and through a corresponding one of the alignment openings in the second layer.

3. A method of fabricating a micro electro-mechanical systems (MEMS) structure, the method comprising:
laminating an intermediate conductive layer of an electromechanical layer of the MEMS structure to a structural layer of a micromechanical structure of the MEMS structure, the electromechanical layer further comprising an outer conductive layer and a piezoelectric layer between the intermediate conductive layer and the outer conductive layer, the micromechanical structure further comprising a spacing layer defining a space open to the structural layer,
wherein laminating the intermediate conductive layer to the structural layer comprises positioning an actuatable portion of the electromechanical layer across the structural layer from the space, the actuatable portion of the electromechanical layer comprising at least a portion of the intermediate conductive layer, at least a portion of the piezoelectric layer, and at least a portion of the outer conductive layer.

4. The method of claim 3, wherein positioning the actuatable portion of the electromechanical layer across the structural layer from the space comprises positioning alignment posts through corresponding alignment openings in each of the electromechanical layer and the micromechanical structure.

5. The method of claim 4, wherein positioning the alignment posts through the alignment openings comprises positioning at least one of the alignment posts through a corresponding one of the alignment openings in the electromechanical layer and through a corresponding one of the alignment openings in the micromechanical structure.

6. The method of claim 1 or 2, wherein:
the first layer comprises an electromechanical layer comprising an intermediate conductive layer, an outer conductive layer, and a piezoelectric layer between the intermediate conductive layer and the outer conductive layer;
the second layer comprises a micromechanical structure comprising a structural layer and a spacing layer defining a space open to the structural layer;
aligning the first layer with the second layer comprises positioning an actuatable portion of the electromechanical layer across the structural layer from the space, the actuatable portion of the electromechanical layer comprising at least a portion of the intermediate conductive layer, at least a portion of the piezoelectric layer, and at least a portion of the outer conductive layer; and
laminating the first layer to the second layer comprises laminating the intermediate conductive layer to the structural layer.

7. The method of claim 4, 5, or 6, wherein laminating the intermediate conductive layer to the structural layer comprises laminating the piezoelectric layer to the structural layer.

8. The method of claim 4, 5, 6, or 7, wherein positioning the alignment posts through the alignment openings comprises positioning at least some of the alignment posts through corresponding alignment openings in the piezoelectric layer.

9. The method of claim 8, further comprising removing alignment portions of the piezoelectric layer to create the alignment openings in the piezoelectric layer.

10. The method of claim 9, wherein removing the alignment portions of the piezoelectric layer comprises causing a laser to remove the alignment portions of the piezoelectric layer.

11. The method of any one of claims 4 to 10, wherein positioning the alignment posts through the alignment openings comprises positioning at least some of the alignment posts through corresponding alignment openings in the structural layer.

12. The method of claim 11, further comprising removing alignment portions of the structural layer to create the alignment openings in the structural layer.

13. The method of claim 12, wherein removing the alignment portions of the structural layer comprises causing a laser to remove the alignment portions of the structural layer.

14. The method of any one of claims 4 to 13, wherein positioning the alignment posts through the alignment openings comprises positioning at least some of the alignment posts through corresponding alignment openings in the spacing layer.

15. The method of claim 14, further comprising removing alignment portions of the spacing layer to create the alignment openings in the spacing layer.

16. The method of claim 15, wherein removing the alignment portions of the spacing layer comprises causing a laser to remove the alignment portions of the spacing layer.

17. The method of any one of claims 4 to 16, wherein positioning the alignment posts through the alignment openings comprises positioning at least three alignment posts through the alignment openings.

18. The method of any one of claims 4 to 17, wherein positioning the alignment posts through the alignment openings comprises positioning the electromechanical layer and the micromechanical structure onto an alignment reference board comprising the alignment posts.

19. The method of claim 18, further comprising manufacturing the alignment reference board.

20. The method of claim 19, wherein manufacturing the alignment reference board comprises 3D printing.

21. The method of claim 19 or 20, wherein manufacturing the alignment reference board comprises computer numerical controlled (CNC) machining.

22. The method of any one of claims 4 to 21, further comprising laminating the spacing layer to a support frame.

23. The method of claim 22, wherein laminating the spacing layer to the support frame comprises:
depositing a support-frame adhesive layer onto the support frame; and
overlaying the spacing layer with the support-frame adhesive layer.

24. The method of claim 23, wherein the support-frame adhesive layer comprises double-sided transfer tape.

25. The method of claim 23 or 24, further comprising removing alignment portions of the support-frame adhesive layer to create alignment openings in the support-frame adhesive layer before depositing the support-frame adhesive layer onto the support frame, the alignment openings in the support-frame adhesive layer corresponding to at least some of the alignment openings in the electromechanical layer and the micromechanical structure.

26. The method of claim 25, wherein removing the alignment portions of the support-frame adhesive layer comprises causing a laser to remove the alignment portions of the support-frame adhesive layer.

27. The method of any one of claims 23 to 26, wherein depositing the support-frame adhesive layer onto the support frame comprises spin-coating.

28. The method of claim 27, wherein the support-frame adhesive layer comprises polypropylene carbonate.

29. The method of any one of claims 22 to 28, wherein laminating the spacing layer to the support frame comprises positioning support posts of the support frame through the alignment openings.

30. The method of any one of claims 22 to 29, further comprising manufacturing the support frame.

31. The method of claim 30, wherein manufacturing the support frame comprises 3D printing.

32. The method of claim 30 or 31, wherein manufacturing the support frame comprises computer numerical controlled (CNC) machining.

33. The method of any one of claims 4 to 32, further comprising depositing the intermediate conductive layer onto the piezoelectric layer before laminating the intermediate conductive layer to the structural layer.

34. The method of claim 33, further comprising:
overlaying the piezoelectric layer with an intermediate shadow mask before depositing the intermediate conductive layer onto the piezoelectric layer; and
removing the intermediate shadow mask after depositing the intermediate conductive layer onto the piezoelectric layer and before laminating the intermediate conductive layer to the structural layer,
wherein the intermediate shadow mask is configured to mask an intermediate masked portion of the piezoelectric layer from deposition of the intermediate conductive layer when the intermediate shadow mask is overlayed with the piezoelectric layer.

35. The method of claim 34, wherein the intermediate shadow mask defines an intermediate shadow mask opening configured to expose an intermediate exposed portion of the piezoelectric layer to deposition of the intermediate conductive layer when the intermediate shadow mask is overlayed with the piezoelectric layer.

36. The method of claim 35, further comprising removing a portion of the intermediate shadow mask to create the intermediate shadow mask opening.

37. The method of claim 36, wherein removing the portion of the intermediate shadow mask comprises causing a laser to remove the portion of the intermediate shadow mask.

38. The method of any one of claims 34 to 37, wherein overlaying the piezoelectric layer with the intermediate shadow mask comprises positioning at least some of the alignment posts through corresponding alignment openings in the intermediate shadow mask.

39. The method of claim 38, further comprising removing alignment portions of the intermediate shadow mask to create the alignment openings in the intermediate shadow mask.

40. The method of claim 39, wherein removing the alignment portions of the intermediate shadow mask comprises causing a laser to remove the alignment portions of the intermediate shadow mask.

41. The method of any one of claims 34 to 40, wherein the intermediate shadow mask comprises a polymer.

42. The method of any one of claims 34 to 41, wherein the intermediate shadow mask comprises polyimide.

43. The method of any one of claims 34 to 42, wherein the intermediate shadow mask comprises glass.

44. The method of any one of claims 34 to 43, wherein the intermediate shadow mask comprises silicon.

45. The method of any one of claims 34 to 44, wherein the intermediate shadow mask comprises a metal.

46. The method of any one of claims 33 to 45 wherein depositing the intermediate conductive layer onto the piezoelectric layer comprises physical vapor deposition

47. The method of any one of claims 33 to 46, wherein depositing the intermediate conductive layer onto the piezoelectric layer comprises electron-beam evaporation.

48. The method of any one of claims 4 to 47, further comprising depositing the outer conductive layer onto the piezoelectric layer.

49. The method of claim 48, further comprising:
overlaying the piezoelectric layer with an outer shadow mask before depositing the outer conductive layer onto the piezoelectric layer; and
removing the outer shadow mask after depositing the outer conductive layer onto the piezoelectric layer,
wherein the outer shadow mask is configured to mask an outer masked portion of the piezoelectric layer from deposition of the outer conductive layer when the outer shadow mask is overlayed with the piezoelectric layer.

50. The method of claim 49, wherein the outer shadow mask defines an outer shadow mask opening configured to expose an outer exposed portion of the piezoelectric layer to deposition of the outer conductive layer when the outer shadow mask is overlayed with the piezoelectric layer.

51. The method of claim 50, further comprising removing a portion of the outer shadow mask to create the outer shadow mask opening.

52. The method of claim 51, wherein removing the portion of the outer shadow mask comprises causing a laser to remove the portion of the outer shadow mask.

53. The method of any one of claims 49 to 52, wherein overlaying the piezoelectric layer with the outer shadow mask comprises positioning at least some of the alignment posts through corresponding alignment openings in the outer shadow mask.

54. The method of claim 53, further comprising removing alignment portions of the outer shadow mask to create the alignment openings in the outer shadow mask.

55. The method of claim 54, wherein removing the alignment portions of the outer shadow mask comprises causing a laser to remove the alignment portions of the outer shadow mask.

56. The method of any one of claims 49 to 55, wherein the outer shadow mask comprises a polymer.

57. The method of any one of claims 49 to 56, wherein the outer shadow mask comprises polyimide.

58. The method of any one of claims 49 to 57, wherein the outer shadow mask comprises glass.

59. The method of any one of claims 49 to 58, wherein the outer shadow mask comprises silicon.

60. The method of any one of claims 49 to 59, wherein the outer shadow mask comprises a metal.

61. The method of any one of claims 48 to 60, wherein depositing the outer conductive layer onto the piezoelectric layer comprises physical vapor deposition.

62. The method of any one of claims 48 to 61, wherein depositing the outer conductive layer onto the piezoelectric layer comprises electron-beam evaporation.

63. The method of any one of claims 3 to 62, wherein the space has a generally circular opening to the structural layer.

64. The method of claim 63, further comprising removing a circular portion of the piezoelectric layer to create a circular opening in the piezoelectric layer before laminating the intermediate conductive layer to the structural layer, the circular opening in the piezoelectric layer having a radius that is less than a radius of the opening of the space to the structural layer, wherein positioning the actuatable portion of the electromechanical layer across the structural layer from the space comprises positioning the circular opening in the piezoelectric layer coaxial with the opening of the space to the structural layer.

65. The method of claim 64, wherein removing the circular portion of the piezoelectric layer comprises causing a laser to remove the circular portion of the piezoelectric layer.

66. The method of any one of claims 3 to 65, further comprising removing a portion of the spacing layer to create the space.

67. The method of claim 66, wherein removing the portion of the spacing layer comprises causing a laser to remove the portion of the spacing layer.

68. The method of any one of claims 3 to 67, wherein laminating the intermediate conductive layer to the structural layer comprises:
depositing a primary adhesive layer onto the structural layer; and
overlaying the intermediate conductive layer with the primary adhesive layer.

69. The method of claim 68 wherein depositing the primary adhesive layer onto the structural layer comprises spin-coating.

70. The method of claim 68 or 69 wherein depositing the primary adhesive layer onto the structural layer comprises ultrasonic coating.

71. The method of claim 68, 69, or 70, wherein the primary adhesive layer comprises an adhesive epoxy.

72. The method of claim 71, wherein the adhesive epoxy is SU-8 photoresist.

73. The method of any one of claims 3 to 72, further comprising laminating the structural layer to the spacing layer before laminating the intermediate conductive layer to the structural layer.

74. The method of claim 73, wherein laminating the structural layer to the spacing layer comprises:
depositing an internal adhesive layer onto the spacing layer; and
overlaying the structural layer with the internal adhesive layer.

75. The method of claim 74 wherein depositing the internal adhesive layer onto the spacing layer comprises spin-coating.

76. The method of claim 74 or 75 wherein depositing the internal adhesive layer onto the spacing layer comprises ultrasonic coating.

77. The method of claim 74, 75, or 76, wherein the internal adhesive layer comprises an adhesive epoxy.

78. The method of claim 77, wherein the adhesive epoxy is SU-8 photoresist.

79. The method of any one of claims 3 to 78, further comprising wire bonding the intermediate conductive layer to an external circuit through a conduit in the micromechanical structure after laminating the intermediate conductive layer to the structural layer, the conduit open to the intermediate conductive layer and to an environment external to the MEMS structure, the external environment comprising the external circuit.

80. The method of claim 79, wherein the structural layer defines a proximal portion of the conduit and the spacing layer defines a distal portion of the conduit.

81. The method of claim 80, further comprising removing a portion of the structural layer to create the proximal portion of the conduit.

82. The method of claim 81, wherein removing the portion of the structural layer comprises causing a laser to remove the portion of the structural layer.

83. The method of claim 80, 81, or 82, further comprising removing a portion of the spacing layer to create the distal portion of the conduit.

84. The method of claim 83, wherein removing the portion of the spacing layer comprises causing a laser to remove the portion of the spacing layer.

85. The method of any one of claims 79 to 84, wherein wire bonding the intermediate conductive layer to the external circuit comprises bonding a first wire to a contact region of the intermediate conductive layer, the contact region of the intermediate conductive layer separate from a moving region of the intermediate conductive layer across the structural layer from the space.

86. The method of claim 85, further comprising wire bonding the outer conductive layer to the external circuit, wherein wire bonding the outer conductive layer to the external circuit comprises bonding a second wire to a contact region of the outer conductive layer, the contact region of the outer conductive layer non-overlapping the contact region of the intermediate conductive layer.

87. The method of claim 86, wherein the contact region of the outer conductive layer is separate from a moving region of the outer conductive layer across the piezoelectric layer, the intermediate conductive layer, and the structural layer from the space.

88. The method of any one of claims 79 to 87, wherein the intermediate conductive layer comprises a first electrode of the electromechanical layer and the outer conductive layer comprises a second electrode of the electromechanical layer.

89. The method of any one of claims 3 to 88, wherein the structural layer comprises a polymer.

90. The method of any one of claims 3 to 89, wherein the structural layer comprises polyimide.

91. The method of any one of claims 3 to 90, wherein the structural layer comprises a Kapton™ polyimide film.

92. The method of any one of claims 3 to 91, wherein the spacing layer comprises a polymer.

93. The method of any one of claims 3 to 92, wherein the spacing layer comprises polyimide.

94. The method of any one of claims 3 to 93, wherein the spacing layer comprises a Kapton™ polyimide film.

95. The method of any one of claims 3 to 94, wherein the piezoelectric layer comprises polyvinylidene difluoride (PVDF).

96. The method of any one of claims 3 to 95, wherein the piezoelectric layer comprises polyvinylidene fluoride-trifluoroethylene (PVDF-TrFe).

97. The method of any one of claims 3 to 96, wherein the intermediate conductive layer comprises a metal.

98. The method of any one of claims 3 to 97, wherein the intermediate conductive layer comprises aluminum.

99. The method of any one of claims 3 to 98, wherein the intermediate conductive layer comprises an aluminum nano film.

100. The method of any one of claims 3 to 99, wherein the outer conductive layer comprises a metal.

101. The method of any one of claims 3 to 100, wherein the outer conductive layer comprises aluminum.

102. The method of any one of claims 3 to 101, wherein the outer conductive layer comprises an aluminum nano film.

103. The method of any one of claims 3 to 102, wherein the piezoelectric layer has a thickness of less than 20 microns.

104. The method of claim 103, wherein the piezoelectric layer has a thickness of about 15 microns.

105. The method of any one of claims 3 to 104, wherein the structural layer has a thickness of less than 30 microns.

106. The method of claim 105, wherein the structural layer has a thickness of about 25 microns.

107. The method of claim 105, wherein the structural layer has a thickness of about 12 microns.

108. The method of any one of claims 3 to 107, wherein the spacing layer has a thickness of less than 200 microns.

109. The method of claim 108, wherein the spacing layer has a thickness of about 150 microns.

110. The method of any one of claims 1 to 109, wherein the MEMS structure is a membrane-based piezoelectric device.

111. The method of any one of claims 1 to 109, wherein the MEMS structure is a transducer.

112. The method of any one of claims 1 to 109, wherein the MEMS structure is a mass sensor.

113. The method of any one of claims 1 to 109, wherein the MEMS structure is a loudspeaker.

114. The method of any one of claims 1 to 109, wherein the MEMS structure is a micropump.

115. A MEMS structure fabricated by the method of any one of claims 1 to 114.
